(19) United States
(12) Patent Application Publication
(10) Pub. No.: US 2025/0169268 A1
(43) Pub. Date: May 22, 2025

(54) PHOTOELECTRIC CONVERSION ELEMENT, PHOTODETECTOR, AND ELECTRONIC APPARATUS

(71) Applicant: SONY SEMICONDUCTOR SOLUTIONS CORPORATION, KANAGAWA (JP)

(72) Inventors: CHIKA SUGIMURA, KANAGAWA (JP); YOSUKE SAITO, KANAGAWA (JP)

(21) Appl. No.: 18/839,907

(22) PCT Filed: Feb. 21, 2023
(86) PCT No.: PCT/JP2023/006249

§ 371 Date: Aug. 20, 2024

(30) Foreign Application Priority Data
Feb. 28, 2022 (JP) 2022-030442

(51) Int. Cl. H10K 30/86; H10K 30/85; H10K 39/32; H10K 39/38; H10K 85/20

(52) U.S. Cl. CPC H10K 30/86; H10K 30/85; H10K 39/32; H10K 85/211; H10K 39/38

(57) ABSTRACT

A photoelectric conversion element according to an embodiment of the present disclosure includes: a first electrode; a second electrode disposed to be opposed to the first electrode; and an organic layer provided between the first electrode and the second electrode, and having a carrier mobility of 10⁻⁵ cm²/Vs or more and 10⁻² cm²/Vs or less, a carrier lifetime of 0.010 μs or more and 1.0 μs or less, and a carrier range of 10 nm or more and 1 μm or less.

### TECHNICAL FIELD

The present disclosure relates to a photoelectric conversion element using an organic semiconductor, a photodetector including the photoelectric conversion element, and an electronic apparatus.

### BACKGROUND ART

For example, PTL 1 discloses a photoelectric conversion element in which a photoelectric conversion layer including a fullerene provided between a first electrode and a second electrode contains a quencher that deactivates an excitation state of the fullerene to thereby enhance light resistance.

### CITATION LIST

### Patent Literature

PTL 1: Japanese Unexamined Patent Application Publication No. 2011-171513

### SUMMARY OF THE INVENTION

A photoelectric conversion element is thus required to have improved light resistance.

It is desirable to provide a photoelectric conversion element, a photodetector, and an electronic apparatus that make it possible to improve light resistance.

A photoelectric conversion element according to an embodiment of the present disclosure includes: a first electrode; a second electrode disposed to be opposed to the first electrode; and an organic layer provided between the first electrode and the second electrode, and having a carrier mobility of 10⁻⁵ cm²/Vs or more and 10⁻² cm²/Vs or less, a carrier lifetime of 0.010 μs or more and 1.0 μs or less, and a carrier range of 10 nm or more and 1 μm or less.

A photodetector according to an embodiment of the present disclosure includes a plurality of pixels each including a photoelectric conversion element that includes one or a plurality of photoelectric conversion sections, in which the photoelectric conversion element according to an embodiment of the present disclosure is provided as the one or the plurality of photoelectric conversion sections.

An electronic apparatus according to an embodiment of the present disclosure includes the photodetector according to an embodiment of the present disclosure.

In the photoelectric conversion element, the photodetector, and the electronic apparatus according to the respective embodiments of the present disclosure, the organic layer is provided between the first electrode and the second electrode disposed to be opposed to each other, in which the organic layer has a carrier mobility of 10⁻⁵ cm²/Vs or more and 10⁻² cm²/Vs or less, a carrier lifetime of 0.010 μs or more and 1.0 μs or less, and a carrier range of 10 nm or more and 1 μm or less. This improves initial element characteristics without using a quencher (e.g., oxygen). In addition, a variation in the element characteristics before and after a light resistance test is decreased.

### BRIEF DESCRIPTION OF THE DRAWINGS

FIG. 1 is a schematic cross-sectional view of an example of a configuration of a photoelectric conversion element according to an embodiment of the present disclosure.

FIG. 2 is a characteristic diagram illustrating a relationship among carrier mobility, a carrier lifetime, and a carrier range of an organic layer of the photoelectric conversion element illustrated in FIG. 1.

FIG. 3 is an explanatory diagram of a process of phosphorescence of a fullerene.

FIG. 4 is a schematic cross-sectional view of an example of a configuration of an imaging element using the photoelectric conversion element illustrated in FIG. 1.

FIG. 5 is a schematic plan view of an example of a pixel configuration of an imaging device including the imaging element illustrated in FIG. 4.

FIG. 6 is an equivalent circuit diagram of the imaging element illustrated in FIG. 4.

FIG. 7 is a schematic view of an arrangement of transistors constituting a controller and a lower electrode of the imaging element illustrated in FIG. 4.

FIG. 8 is an explanatory cross-sectional view of a method of manufacturing the imaging element illustrated in FIG. 4.

FIG. 9 is a cross-sectional view of a step subsequent to FIG. 8.

FIG. 10 is a cross-sectional view of a step subsequent to FIG. 9.

FIG. 11 is a cross-sectional view of a step subsequent to FIG. 10.

FIG. 12 is a cross-sectional view of a step subsequent to FIG. 11.

FIG. 13 is a cross-sectional view of a step subsequent to FIG. 12.

FIG. 14 is a timing diagram illustrating an operation example of the imaging element illustrated in FIG. 4.

FIG. 15 is a schematic cross-sectional view of an example of a configuration of an imaging element according to Modification Example 1 of the present disclosure.

FIG. 16 is a schematic cross-sectional view of an example of a configuration of an imaging element according to Modification Example 2 of the present disclosure.

FIG. 17A is a schematic cross-sectional view of an example of a configuration of an imaging element according to Modification Example 3 of the present disclosure.

FIG. 17B is a schematic view of a planar configuration of the imaging element illustrated in FIG. 17A.

FIG. 18A is a schematic cross-sectional view of an example of a configuration of an imaging element according to Modification Example 4 of the present disclosure.

FIG. 18B is a schematic view of a planar configuration of the imaging element illustrated in FIG. 18A.

FIG. 19 is a schematic cross-sectional view of another example of the configuration of the imaging element of Modification Example 2 according to another modification example of the present disclosure.

FIG. 20A is a schematic cross-sectional view of another example of the configuration of the imaging element of Modification Example 3 according to another modification example of the present disclosure.

FIG. 20B is a schematic view of a planar configuration of the imaging element illustrated in FIG. 20A.

FIG. 21A is a schematic cross-sectional view of another example of the configuration of the imaging element of Modification Example 4 according to another modification example of the present disclosure.

FIG. 21B is a schematic view of a planar configuration of the imaging element illustrated in FIG. 21A.

FIG. 22 is a block diagram illustrating an overall configuration of an imaging device including the imaging element illustrated in FIG. 4 or other drawings.

FIG. 23 is a block diagram illustrating an example of a configuration of an electronic apparatus using the imaging device illustrated in FIG. 22.

FIG. 24A is a schematic view of an example of an overall configuration of a photodetection system using the imaging device illustrated in FIG. 22.

FIG. 24B is a diagram illustrating an example of a circuit configuration of the photodetection system illustrated in FIG. 24A

FIG. 25 is a view depicting an example of a schematic configuration of an endoscopic surgery system.

FIG. 26 is a block diagram depicting an example of a functional configuration of a camera head and a camera control unit (CCU).

FIG. 27 is a block diagram depicting an example of schematic configuration of a vehicle control system.

FIG. 28 is a diagram of assistance in explaining an example of installation positions of an outside-vehicle information detecting section and an imaging section.

### MODES FOR CARRYING OUT THE INVENTION

In the following, description is given of embodiments of the present disclosure in detail with reference to the drawings. The following description is merely a specific example of the present disclosure, and the present disclosure should not be limited to the following aspects. Moreover, the present disclosure is not limited to arrangements, dimensions, dimensional ratios, and the like of each component illustrated in the drawings. It is to be noted that the description is given in the following order.
1. Embodiment (An example of a photoelectric conversion element including, between electrodes disposed to be opposed to each other, an organic layer having predetermined carrier mobility, carrier lifetime, and carrier range)
   1-1. Configuration of Photoelectric Conversion Element
   1-2. Configuration of Imaging Element
   1-3. Method of Manufacturing Imaging Element
   1-4. Signal Acquisition Operation of Imaging Element
   1-5. Workings and Effects
2. Modification Examples
   2-1. Modification Example 1 (Another example of the configuration of the imaging element)
   2-2. Modification Example 2 (Another example of the configuration of the imaging element)
   2-3. Modification Example 3 (Another example of the configuration of the imaging element)
   2-4. Modification Example 4 (Another example of the configuration of the imaging element)
   2-5. Modification Example 5 (Another modification example of the imaging element)
3. Application Examples
   4. Practical Application Examples
   5. Examples

### 1. FIRST EMBODIMENT

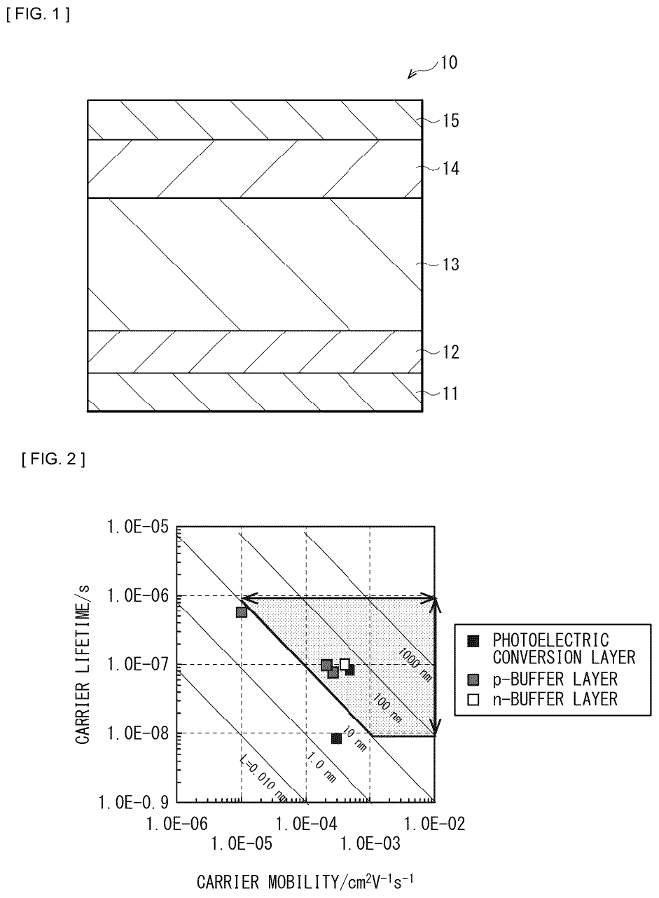

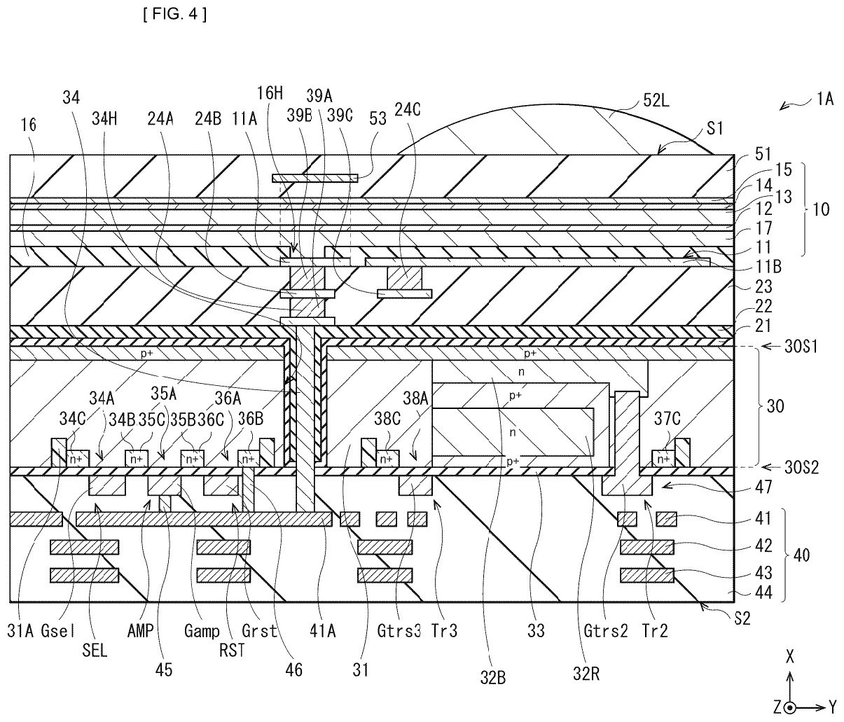

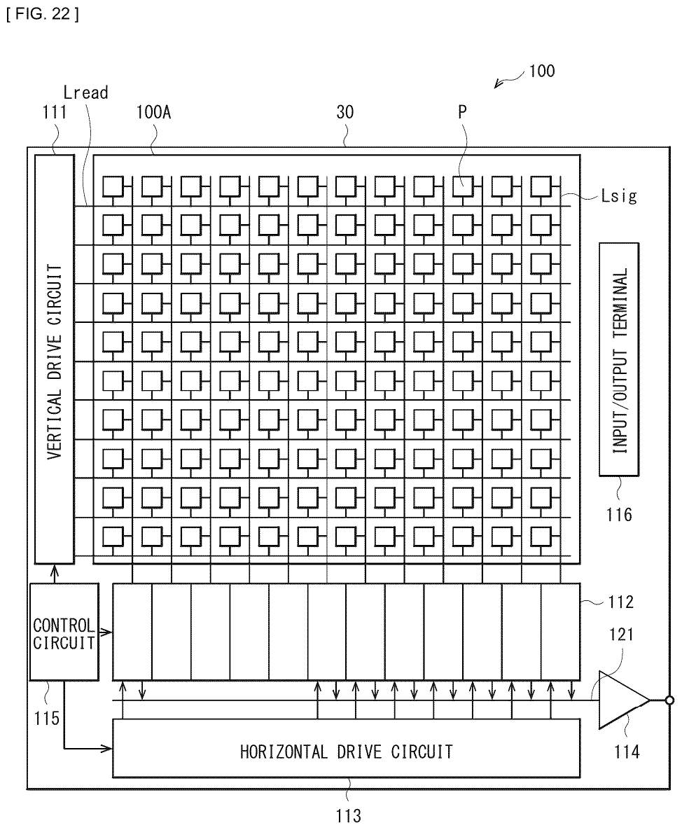

FIG. 1 schematically illustrates an example of a cross-sectional configuration of a photoelectric conversion element (a photoelectric conversion element 10) according to an embodiment of the present disclosure. The photoelectric conversion element 10 is used as an imaging element (an imaging element 1A, see, e.g., FIG. 4) that constitutes one pixel (a unit pixel P) in an imaging device (an imaging device 100, see, e.g., FIG. 22) such as a CMOS (Complementary Metal Oxide Semiconductor) image sensor to be used, for example, in an electronic apparatus such as a digital still camera or a video camera. The photoelectric conversion element 10 has a configuration in which an n-buffer layer 12, a photoelectric conversion layer 13, and a p-buffer layer 14 are stacked in this order as organic layers between a lower electrode 11 and an upper electrode 15 disposed to be opposed to each other. The organic layer of the present embodiment has a carrier mobility of 10⁻⁵ cm²/Vs or more and 10⁻² cm²/Vs or less, a carrier lifetime of 0.010 μs or more and 1.0 μs or less, and a carrier range of 10 nm or more and 1 μm or less.

### (1-1. Configuration of Photoelectric Conversion Element)

The photoelectric conversion element 10 absorbs light corresponding to a portion or the whole of a wavelength of a selective wavelength region (e.g., a visible light region and a near-infrared light region of 400 nm or more and less than 1300 nm) to generate excitons (e.g., electron-hole pairs). As for the photoelectric conversion element 10, in an imaging element (e.g., imaging element 1A) described later, for example, electrons among the electron-hole pairs generated through photoelectric conversion are read, as signal charge, from a side of the lower electrode 11. Hereinafter, description is given of configurations, materials, and the like of each of the sections by exemplifying a case where electrons are read as signal charge from the side of the lower electrode 11.

The lower electrode 11 (cathode) is, for example, configured by an electrically-conductive film having light transmissivity. The lower electrode 11 preferably has a work function of 4.0 eV or more and 5.5 eV or less. Examples of the constituent material of such a lower electrode 11 include indium tin oxide (ITO) as In₂O₃ doped with tin (Sn) as a dopant. As for a crystalline property of the thin film of ITO, the crystalline property may be higher or may be lower (comes close to amorphous). In addition thereto, other examples of the constituent material of the lower electrode 11 include a tin oxide (SnO₂)-based material doped with a dopant, e.g., ATO doped with Sb as a dopant and FTO doped with fluorine as a dopant. In addition, zinc oxide (ZnO) or a zinc oxide-based material doped with a dopant may be used. Examples of the ZnO-based material include aluminum zinc oxide (AZO) doped with aluminum (Al) as a dopant, gallium zinc oxide (GZO) doped with gallium (Ga), boron zinc oxide doped with boron (B), and indium zinc oxide (IZO) doped with indium (In). Further, zinc oxide (IGZO, In—GaZnO₄) doped with indium and gallium as dopants may be used. Additionally, as the constituent material of the lower electrode 11, for example, CuI, InSbO₄, ZnMgO, CuInO₂, MgIN₂O₄, CdO, ZnSnO₃, or TiO₂ may be used, or a spinel type oxide or an oxide having a YbFe₂O₄ structure may be used.

In addition, in a case where light transmissivity is unnecessary for the lower electrode 11 (e.g., in a case where light is incident from a side of the upper electrode 15), a single metal or alloy may be used that has a low work function (e.g., φ=3.5 eV to 4.5 eV). Specific examples thereof include an alkali metal (e.g., lithium (Li), sodium (Na), and potassium (K)) and a fluoride or oxide of such an alkali metal, and an alkali earth metal (e.g., magnesium (Mg) and calcium (Ca)) and a fluoride or oxide of such an alkali earth metal. Other examples thereof include aluminum (Al), Al—Si—Cu alloy, zinc (Zn), tin (Sn), thallium (Tl), Na—K alloy, Al—Li alloy, Mg—Ag alloy, In, and a rare earth metal such as ytterbium (Yb), and an alloy of such a material.

Further, other examples of the material constituting the lower electrode 11 include electrically-conductive substances including a metal such as platinum (Pt), gold (Au), palladium (Pd), chromium (Cr), nickel (Ni), aluminum (Al), silver (Ag), tantalum (Ta), tungsten (W), copper (Cu), titanium (Ti), indium (In), tin (Sn), iron (Fe), cobalt (Co), and molybdenum (Mo), an alloy containing such a metal element, electrically-conductive particles of such a metal, electrically-conductive particles of an alloy containing such a metal, polysilicon containing impurities, a carbon-based material, an oxide semiconductor, a carbon nano-tube, and graphene. Other examples of the material constituting the lower electrode 11 include an organic material (electrically-conductive high polymer) such as poly(3,4-ethylenedioxythiophene)/polystyrene sulfonic acid [PEDOT/PSS]. In addition, a paste or ink obtained by mixing the above-described material with a binder (high polymer) may be cured for use as an electrode.

The lower electrode 11 may be formed as a monolayer film or a stacked film including such a material as described above. A film thickness (hereinafter, simply referred to as a thickness) of the lower electrode 11 in a stacking direction is, for example, 20 nm or more and 200 nm or less, and preferably 30 nm or more and 150 nm or less.

The n-buffer layer 12 corresponds to a specific example of an “organic layer” of the present disclosure. The n-buffer layer 12 selectively transports electrons, of electric charge generated in the photoelectric conversion layer 13, to the lower electrode 11, and inhibits injection of holes from the side of the lower electrode 11. The n-buffer layer 12 may be formed using a material having electron transportability (electron-transporting material). The n-buffer layer 12 has a thickness of 5 nm or more and 20 nm or less, for example.

The photoelectric conversion layer 13 corresponds to a specific example of the “organic layer” of the present disclosure. The photoelectric conversion layer 13 absorbs, for example, 60% or more of a predetermined wavelength included at least in a visible light region to a near-infrared region to perform electric charge separation. The photoelectric conversion layer 13 absorbs light beams corresponding to all or a portion of wavelengths in the visible light region and the near-infrared light region of 400 nm or more and less than 1300 nm, for example. The photoelectric conversion layer 13 includes two or more types of organic materials that each function as a p-type semiconductor or an n-type semiconductor, for example, and has, within the layer, a junction surface (a p/n junction surface) between the p-type semiconductor and the n-type semiconductor. In addition thereto, the photoelectric conversion layer 13 may have a stacked structure of a layer including a p-type semiconductor (a p-type semiconductor layer) and a layer including an n-type semiconductor (an n-type semiconductor layer) (p-type semiconductor layer/n-type semiconductor layer), a stacked structure of a p-type semiconductor layer and a mixed layer (a bulk hetero layer) of a p-type semiconductor and an n-type semiconductor (p-type semiconductor layer/bulk hetero layer), or a stacked structure of an n-type semiconductor layer and a bulk hetero layer (n-type semiconductor layer/bulk hetero layer). Further, the photoelectric conversion layer 13 may be formed only by a mixed layer (a bulk hetero layer) of a p-type semiconductor and an n-type semiconductor.

The p-type semiconductor is a hole-transporting material that relatively functions as an electron donor. The n-type semiconductor is as an electron-transporting material that relatively functions as an electron acceptor. The photoelectric conversion layer 13 provides a place where excitons (electron-hole pairs) generated upon light absorption are separated into electrons and holes. Specifically, the electron-hole pairs are separated into electrons and holes at an interface (p/n junction surface) between the electron donor and the electron acceptor.

The photoelectric conversion layer 13 may further include, in addition to the p-type semiconductor and the n-type semiconductor, an organic material that absorbs light in a predetermined wavelength region while transmitting light in another wavelength region, i.e., a so-called coloring material. In a case where the photoelectric conversion layer 13 is formed using three types of organic materials of a p-type semiconductor, an n-type semiconductor, and a coloring material, the p-type semiconductor and the n-type semiconductor are each preferably a material having light transmissivity in a visible light region. This allows the photoelectric conversion layer 13 to selectively and photoelectrically convert light in a wavelength region to be absorbed by the coloring material.

The photoelectric conversion layer 13 has a thickness of, for example, 10 nm or more and 500 nm or less, and preferably has a thickness of 100 nm or more and 400 nm or less.

The p-buffer layer 14 corresponds to a specific example of the “organic layer” of the present disclosure. The p-buffer layer 14 selectively transports holes, of electric charge generated in the photoelectric conversion layer 13, to the upper electrode 15, and inhibits movement of electrons to the side of the upper electrode 15. The p-buffer layer 14 may be formed using a material having hole transportability (hole-transporting material). The p-buffer layer 14 has a thickness of, for example, 5 nm or more and 100 nm or less, and preferably has a thickness of 5 nm or more and 50 nm or less. More preferably, the p-buffer layer 14 has a thickness of 5 nm or more and 20 nm or less.

FIG. 2 illustrates a relationship among carrier mobility, a carrier lifetime, and a carrier range of the organic layer including the n-buffer layer 12, the photoelectric conversion layer 13, and the p-buffer layer 14 of the present embodiment.

In a typical organic photoelectric conversion element, oxygen is used as a quencher when producing the element to thereby achieve an improvement in light resistance. As a method of mixing oxygen, a method is used that involves forming, as a film, an upper electrode (e.g., an ITO electrode) and then exposing the element to the atmosphere for about one day. However, such a method results in an issue in which oxygen serves as a carrier trap, thus lowering initial characteristics (e.g., external quantum efficiency (EQE)). In addition, there is an issue in which it is difficult to control oxygen as the quencher, thus causing the EQE to be decreased after a light resistance test.

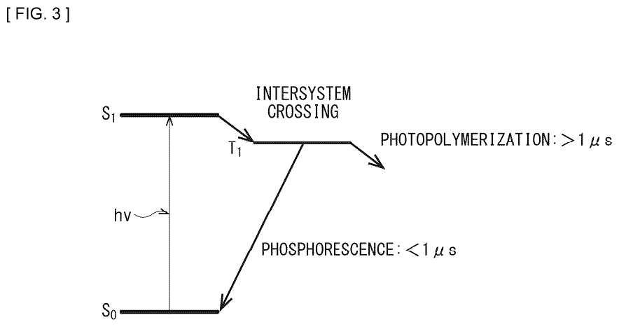

FIG. 3 illustrates a process of phosphorescence of a fullerene. As illustrated in FIG. 3, when absorbing optical energy, a fullerene C₆₀ molecule is excited from a ground state (S₀) to a singlet state (S₁), and comes into a triplet state (T₁) by intersystem crossing. At this time, in a case where a carrier lifetime is larger than 1 μs, photopolymerization between fullerene C₆₀ molecules proceeds. When the carrier lifetime is 1 μs or less, the fullerene C₆₀ molecule emits phosphorescence without being polymerized, and return to the ground state (S₀). When a polymerization rate of the fullerene is increased, sensitivity is decreased, thus leading to deterioration of photoelectric conversion efficiency.

When an electric field intensity to be applied to the photoelectric conversion layer 13 is 10⁴ V/cm or more and 10⁶ V/cm or less, for example, the organic layer of the present embodiment has a carrier mobility of 10⁻⁵ cm²/Vs or more and 10⁻² cm²/Vs or less, a carrier lifetime of 0.010 μs or more and 1.0 μs or less, and a carrier range of 10 nm or more and 1 μm or less. Specifically, for example, the n-buffer layer 12 has an electron mobility of 10⁻⁵ cm²/Vs or more and 10⁻² cm²/Vs or less, an electron lifetime of 0.010 μs or more and 1.0 μs or less, and an electron range of 10 nm or more and 1 μm or less. In the photoelectric conversion layer 13, for example, mobility of carriers including electrons and holes is 10⁻⁵ cm²/Vs or more and 10⁻² cm²/Vs or less, a lifetime of carriers including electrons and holes is 0.010 μs or more and 1.0 μs or less, and a range of carriers including electrons and holes is 10 nm or more and 1 μm or less. For example, the p-buffer layer 14 has a hole mobility of 10⁻⁵ cm²/Vs or more and 10⁻² cm²/Vs or less, a hole lifetime of 0.010 μs or more and 1.0 μs or less, and a hole range of 10 nm or more and 1 μm or less.

The carrier mobility, the carrier lifetime, and the carrier range are determined as follows.

As for evaluation of the carrier mobility (μ), a space charge limited current (Space Charge Limited Current; SCLC) method is used. In an organic semiconductor having low mobility, a current does not follow Ohm's law, and an SCLC proportional to the square of a voltage is observed. At this time, a flowing current is represented by the following numerical expression (1) to determine the carrier mobility. Here, J denotes a current density, & and co denote permittivities of the organic semiconductor and vacuum, u denotes carrier mobility, V denotes a voltage (2 V to be used), and L (200 nm to be used) denotes a film thickness of a sample. As a device structure, a hole-only device or an electron-only device is used instead of the photoelectric conversion element. The hole-only device has a device structure in which only holes are extracted, and molybdenum oxide (MoO₃) is used for a buffer. The electron-only device has a device structure in which only electrons are extracted, and lithium fluoride (LiF) is used for a buffer.

$$\begin{matrix}[ Numerical Expression 1 ] & \\ J = 9 ε {ε}_{0} μ {V}^{2} / 8 {L}^{3} & ( 1 )\end{matrix}$$

As for evaluation of the carrier lifetime (τ), a photo-CELIV (photo-Charge-carrier extraction by linearly increasing voltage) method is used. Carriers charged in the organic layer by pulsed light are released to an external circuit by applying a pulse voltage. At this time, the carrier lifetime is determined from a waveform of a flowing current using the following mathematical expression (2). Here, γ denotes a substance-specific constant (fitting parameter), n (0) denotes an initial carrier density, and B₀ denotes a recombination constant.

$$\begin{matrix}[ Numerical Expression 2 ] & \\ τ = {( Y / n ( 0 ) {β}_{0} )}^{1 / Y} & ( 2 )\end{matrix}$$

A carrier range (L) is determined from a calculation using the following mathematical expression (3) when an electric field intensity (E) is 10⁵ V/cm.

$$\begin{matrix}[ Numerical Expression 3 ] & \\ L = μ τ E & ( 3 )\end{matrix}$$

It is preferable to use, for each of the n-buffer layer 12, the photoelectric conversion layer 13, and the p-buffer layer 14, an organic semiconductor with high carrier mobility and a short carrier lifetime. Specifically, the n-buffer layer 12 is preferably formed using an electron-transporting material (n-type semiconductor) having high electron mobility and a short electron lifetime. The p-buffer layer 14 is preferably formed using a hole-transporting material (p-type semiconductor) having high hole mobility and a short hole lifetime.

Examples of the n-type semiconductor include those including a x-conjugated system with high mobility and including an easily rotatable substituent. Examples thereof include a fullerene and a fullerene derivative typified by a higher fullerene, such as fullerene C₆₀, fullerene C₇₀, or fullerene C₇₄, endohedral fullerene, or the like. Examples of a substituent included in the fullerene derivative include a halogen atom, a straight-chain, branched, or cyclic alkyl group or phenyl group, a group including a straight-chain or condensed aromatic compound, a group including a halide, a partial fluoroalkyl group, a perfluoroalkyl group, a silyl alkyl group, a silyl alkoxy group, an aryl silyl group, an aryl sulfanyl group, an alkyl sulfanyl group, an aryl sulfonyl group, an alkyl sulfonyl group, an aryl sulfide group, an alkyl sulfide group, an amino group, an alkyl amino group, an aryl amino group, a hydroxy group, an alkoxy group, an acyl amino group, an acyloxy group, a carbonyl group, a carboxy group, a carboxamide group, a carboalkoxy group, an acyl group, a sulfonyl group, a cyano group, a nitro group, a group including a chalcogenide, a phosphine group, a phosphone group, and derivatives thereof. Specific examples of the fullerene derivative include fullerene fluoride, a PCBM fullerene compound, a fullerene multimer, and the like.

Examples of the p-type semiconductor include those including a x-conjugated system with high mobility and including an easily rotatable substituent. Examples thereof include thienoacene-based materials typified by a naphthalene derivative, an anthracene derivative, a phenanthrene derivative, a pyrene derivative, a perylene derivative, a tetracene derivative, a pentacene derivative, a quinacridone derivative, a thiophene derivative, a thienothiophene derivative, a benzothiophene derivative, a benzothienobenzothiophene (BTBT) derivative, a dinaphthothienothiophene (DNTT) derivative, a dianthracenothienothiophene (DATT) derivative, a benzobisbenzothiophene (BBBT) derivative, a thienobisbenzothiophene (TBBT) derivative, a dibenzothienobisbenzothiophene (DBTBT) derivative, a dithienobenzodithiophene (DTBDT) derivative, a dibenzothienodithiophene (DBTDT) derivative, a benzodithiophene (BDT) derivative, a naphthodithiophene (NDT) derivative, an anthracenodithiophene (ADT) derivative, a tetracenodithiophene (TDT) derivative, and a pentacenodithiophene (PDT) derivative. In addition, examples of the p-type semiconductor include a triphenylamine derivative, a carbazole derivative, a picene derivative, a chrysene derivative, for example, a fluoranthene derivative, a phthalocyanine derivative, a subphthalocyanine derivative, a subporphyrazine derivative, a metal complex including a heterocyclic compound as a ligand, a polythiophene derivative, a polybenzothiadiazole derivative, a polyfluorene derivative, and the like.

The photoelectric conversion layer 13 is preferably formed using an electron-transporting material (n-type semiconductor) having high electron mobility and a short electron lifetime as well as a hole-transporting material having high hole mobility and a short hole lifetime. Examples of the electron-transporting material (n-type semiconductor) include, among the above-described n-type semiconductors, a fullerene and a fullerene derivative typified by a higher fullerene, such as fullerene C₆₀, fullerene C₇₀, or fullerene C₇₄, endohedral fullerene, or the like. Further, the photoelectric conversion layer 13 is preferably formed using a coloring material including an easily rotatable substituent and a x-conjugated system having a high absorption coefficient with respect to light in a desired wavelength region.

In the same manner as the lower electrode 11, the upper electrode 15 (anode) is configured by, for example, an electrically-conductive film having light transmissivity. Examples of a constituent material of the upper electrode 15 include indium tin oxide (ITO) which is a In₂O₃ doped with tin (Sn) as a dopant. The crystalline property of a thin film of the ITO may be higher or lower (comes close to amorphous) in the crystalline property. In addition thereto, other examples of the constituent material of the lower electrode 11 include a tin oxide (SnO₂)-based material doped with a dopant, e.g., ATO doped with Sb as a dopant and FTO doped with fluorine as a dopant. In addition, zinc oxide (ZnO) or a zinc oxide-based material doped with a dopant may be used. Examples of the ZnO-based material include aluminum zinc oxide (AZO) doped with aluminum (Al) as a dopant, gallium zinc oxide (GZO) doped with gallium (Ga), boron zinc oxide doped with boron (B), and indium zinc oxide (IZO) doped with indium (In). Further, zinc oxide (IGZO, In—GaZnO₄) doped with indium and gallium as dopants may be used. Additionally, as the constituent material of the lower electrode 11, for example, CuI, InSbO₄, ZnMgO, CuInO₂, MgIN₂O₄, CdO, ZnSnO₃, TiO₂, or the like may be used, or a spinel type oxide or an oxide having an YbFe₂O₄ structure may be used.

In addition, in a case where light transmissivity is unnecessary for the upper electrode 15, a single metal or alloy may be used that has a high work function (e.g., φ=4.5 eV to 5.5 eV). Specific examples thereof include Au, Ag, Cr, Ni, Pd, Pt, Fe, iridium (Ir), germanium (Ge), osmium (Os), rhenium (Re), tellurium (Te), and alloys thereof.

Further, other examples of the material constituting the upper electrode 15 include electrically-conductive substances including a metal such as Pt, Au, Pd, Cr, Ni, Al, Ag, Ta, W, Cu, Ti, In, Sn, Fe, Co, and Mo, an alloy containing such a metal element, electrically-conductive particles of such a metal, electrically-conductive particles of an alloy containing such a metal, polysilicon containing impurities, a carbon-based material, an oxide semiconductor, a carbon nano-tube, and graphene. Other examples of the material constituting the upper electrode 15 include an organic material (electrically-conductive high polymer) such as PEDOT/PSS. In addition, a paste or ink obtained by mixing the above-described material with a binder (high polymer) may be cured for use as an electrode.

The upper electrode 15 may be formed as a monolayer film or a stacked film including such a material as described above. The upper electrode 15 has a thickness of, for example, 20 nm or more and 200 nm or less, and preferably 30 nm or more and 150 nm or less.

It is to be noted that another layer, in addition to the n-buffer layer 12, the photoelectric conversion layer 13, and the p-buffer layer 14, may be further provided between the lower electrode 11 and the upper electrode 15. For example, an underlying layer, in addition to the n-buffer layer 12, may be provided between the lower electrode 11 and the photoelectric conversion layer 13. A work function adjustment layer, in addition to the p-buffer layer, may be provided between the photoelectric conversion layer 13 and the upper electrode 15.

Light incident on the photoelectric conversion element 10 is absorbed by the photoelectric conversion layer 13. Excitons (electron/hole pairs) thus generated undergo exciton separation, i.e., dissociate into electrons and holes, at the interface (p/n junction surface) between the p-type semiconductor and the n-type semiconductor that constitute the photoelectric conversion layer 13. The carriers (electrons and holes) generated here are transported to respective different electrodes by diffusion due to a concentration difference between the carriers and by an internal electric field due to a difference in the work functions between an anode and a cathode, and are detected as photocurrents. Specifically, electrons separated at the p/n junction surface are taken out from the lower electrode 11 via the n-buffer layer 12. Holes separated at the p/n junction surface are taken out from the upper electrode 15 via the p-buffer layer 14. It is to be noted that transporting directions of electrons and holes may also be controlled by applying a potential between the lower electrode 11 and the upper electrode 15.

### (1-2. Configuration of Imaging Element)

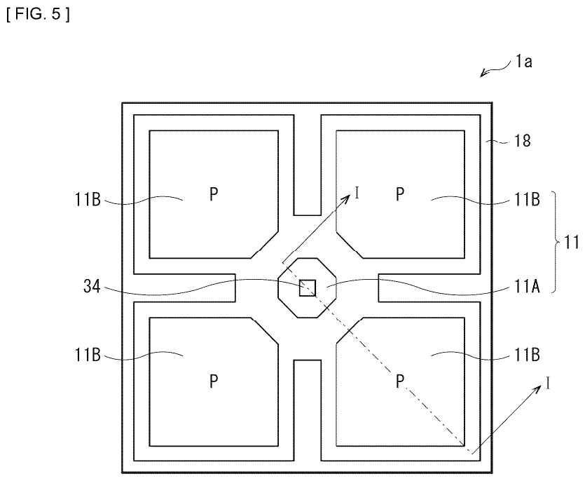

FIG. 4 schematically illustrates an example of a cross-sectional configuration of an imaging element (imaging element 1A) using the photoelectric conversion element 10 described above. FIG. 5 schematically illustrates an example of a planar configuration of the imaging element 1A illustrated in FIG. 4, and FIG. 4 illustrates a cross-section taken along a line I-I illustrated in FIG. 5. The imaging element 1A constitutes, for example, one pixel (unit pixel P) repeatedly arranged in array in a pixel section 100A of the imaging device 100 illustrated in FIG. 22. In the pixel section 100A, as illustrated in FIG. 5, for example, a pixel unit 1a including four pixels arranged in two rows x two columns serves as a repeating unit, and is repeatedly arranged in an array including a row direction and a column direction.

The imaging element 1A is a so-called vertical spectroscopic imaging element in which one photoelectric conversion section formed using, for example, an organic material and two photoelectric conversion sections (photoelectric conversion regions 32B and 32R) including, for example, an inorganic material are stacked in a vertical direction. The photoelectric conversion element 10 described above may be used as a photoelectric conversion section constituting the imaging element 1A. Hereinafter, the photoelectric conversion section having a configuration similar to that of the photoelectric conversion element 10 described above is denoted by the same reference numeral 10 for description.

In the imaging element 1A, a photoelectric conversion section 10 is provided on a side of a back surface (a first surface 30S1) of a semiconductor substrate 30. The photoelectric conversion regions 32B and 32R are formed to be embedded in the semiconductor substrate 30, and are stacked in a thickness direction of the semiconductor substrate 30.

The photoelectric conversion section 10 and the photoelectric conversion regions 32B and 32R selectively detect light beams in wavelength regions different from each other to perform photoelectric conversion. For example, the photoelectric conversion section 10 acquires a green (G) color signal. The photoelectric conversion regions 32B and 32R respectively acquire blue (B) and red (R) color signals depending on a difference in absorption coefficients. This enables the imaging element 1A to acquire a plurality of types of color signals in one pixel without using color filters.

It is to be noted that, as for the imaging element 1A, description is given of a case where electrons of electron/hole pairs generated by photoelectric conversion are read as signal charge. In addition, in the diagram, “+ (plus)” attached to “p” and “n” indicates a higher p-type or n-type impurity concentration.

The semiconductor substrate 30 is configured by, for example, an n-type silicon (Si) substrate, and includes a p-well 31 in a predetermined region. A second surface (a front surface of the semiconductor substrate 30) 30S2 of the p-well 31 is provided with, for example, various floating diffusions (floating diffusion layers) FD (e.g., FD1, FD2, and FD3), various transistors Tr (e.g., a vertical transistor (transfer transistor) Tr2, a transfer transistor Tr3, an amplifier transistor (modulation element) AMP, and a reset transistor RST). The second surface 30S2 of the semiconductor substrate 30 is further provided with a multilayer wiring layer 40 with a gate insulating layer 33 interposed therebetween. The multilayer wiring layer 40 has a configuration in which, for example, wiring layers 41, 42, and 43 are stacked inside an insulating layer 44. In addition, a peripheral part of the semiconductor substrate 30 is provided with a peripheral circuit (unillustrated) including a logic circuit or the like.

A protective layer 51 is provided above the photoelectric conversion section 10. In the protective layer 51, for example, wiring is provided that electrically couples the upper electrode 15 and a peripheral circuit part to each other around a light-blocking film 53 or the pixel section 100A. An optical member such as an on-chip lens 52L or a planarization layer (unillustrated) is further disposed above the protective layer 51.

It is to be noted that, in FIG. 4, a side of the first surface 30S1 of the semiconductor substrate 30 is denoted by a light incident surface S1, and a side of the second surface 30S2 thereof is denoted by a wiring layer side S2.

Hereinafter, description is given in detail of configurations, materials, and the like of each of the sections.

The photoelectric conversion section 10 includes the n-buffer layer 12, the photoelectric conversion layer 13, and the p-buffer layer 14, which are stacked in this order between the lower electrode 11 and the upper electrode 15 disposed to be opposed to each other. In the imaging element 1A, the lower electrode 11 includes a plurality of electrodes (e.g., two of a readout electrode 11A and an accumulation electrode 11B). For example, an insulating layer 16 and a semiconductor layer 17 are stacked in this order between the lower electrode 11 and the n-buffer layer 12. The readout electrode 11A, of the lower electrode 11, is electrically coupled to the semiconductor layer 17 via an opening 16H provided in the insulating layer 16.

The readout electrode 11A is provided to transfer electric charge generated in the photoelectric conversion layer 13 to the floating diffusion FD1, and is coupled to the floating diffusion FD1 via, for example, an upper second contact 24B, a pad section 39B, an upper first contact 29A, a pad section 39A, a through-electrode 34, a coupling section 41A, and a lower second contact 46.

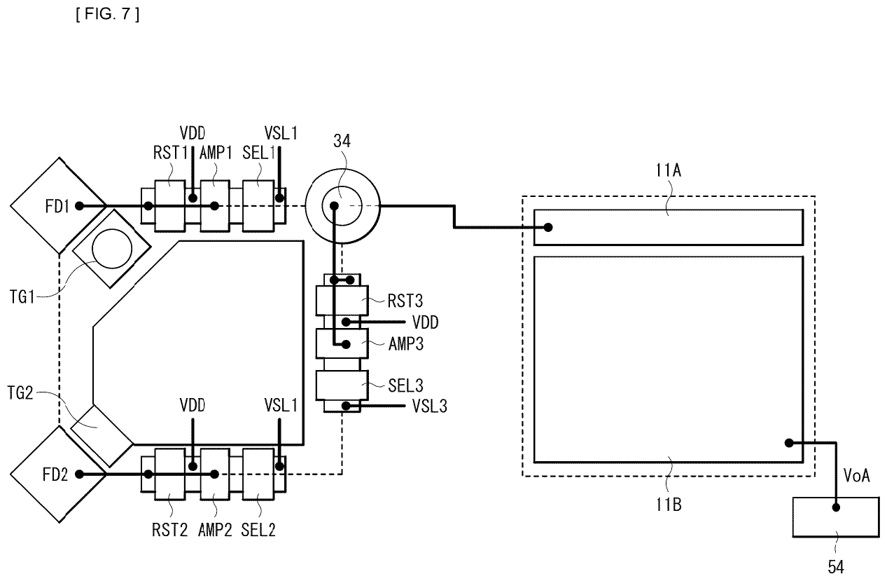

The accumulation electrode 11B is provided to accumulate, as signal charge, electrons, of electric charge generated in the photoelectric conversion layer 13, in the semiconductor layer 17. The accumulation electrode 11B is provided in a region that is opposed to light-receiving surfaces of the photoelectric conversion regions 32B and 32R formed in the semiconductor substrate 30 and covers these light-receiving surfaces. The accumulation electrode 11B is preferably larger than the readout electrode 11A; this enables much electric charge to be accumulated. As illustrated in FIG. 7, a voltage application section 54 is coupled to the accumulation electrode 11B via wiring such as an upper third contact 24C and a pad section 39C.

The insulating layer 16 is provided to electrically separate the accumulation electrode 11B and the semiconductor layer 17 from each other. The insulating layer 16 is provided on an interlayer insulating layer 23, for example, to cover the lower electrode 11. The insulating layer 16 is configured by, for example, a monolayer film including one of silicon oxide (SiOₓ), silicon nitride (SiNₓ) or silicon oxynitride (SiOₓN_{y}), or a stacked film including two or more thereof. The insulating layer 16 has a thickness of, for example, 20 nm or more and 500 nm or less.

The semiconductor layer 17 is provided to accumulate signal charge generated in the photoelectric conversion layer 13. The semiconductor layer 17 is preferably formed using a material having higher electric charge mobility than that of the photoelectric conversion layer 13 and having a larger band gap. For example, the band gap of a constituent material of the semiconductor layer 17 is preferably 3.0 eV or more. Examples of such a material include an oxide semiconductor such as IGZO and an organic semiconductor. Examples of the organic semiconductor include transition metal dichalcogenide, silicon carbide, diamond, graphene, a carbon nano-tube, a condensed polycyclic hydrocarbon compound, and a condensed heterocyclic compound. The semiconductor layer 17 has a thickness of, for example, 10 nm or more and 300 nm or less. Providing the semiconductor layer 17 configured by the above-described material between the lower electrode 11 and the photoelectric conversion layer 13 prevents recombination of electric charge during electric charge accumulation, thus making it possible to improve transfer efficiency.

Although not illustrated in FIG. 1, a shield electrode 18 is further provided around the pixel unit 1a including four pixels arranged in two rows x two columns, for example. The shield electrode 18 is provided to prevent capacitive coupling between pixel units 1a adjacent to each other; for example, a fixed potential is applied thereto. The shield electrode 18 further extends between pixels adjacent to each other in the row direction (a Z-axis direction) and the column direction (a X-axis direction) in the pixel unit 1a.

It is to be noted that FIG. 4 illustrates an example in which the semiconductor layer 17, the n-buffer layer 12, the photoelectric conversion layer 13, the p-buffer layer 14, and the upper electrode 15 are provided as continuous layers common to a plurality of pixels (unit pixels P, see FIG. 22); however, this is not limitative. The semiconductor layer 17, the n-buffer layer 12, the photoelectric conversion layer 13, the p-buffer layer 14, and the upper electrode 15 may be formed separately for each unit pixel P, for example.

A layer having fixed electric charge (a fixed charge layer) 21, a dielectric layer 22 having an insulation property, and the interlayer insulating layer 23 are provided in this order from the side of the first surface 30S1 of the semiconductor substrate 30, for example, between the semiconductor substrate 30 and the lower electrode 11.

The fixed charge layer 21 may be a film having positive fixed electric charge, or may be a film having negative fixed electric charge. As for the constituent material, the fixed charge layer 21 is preferably formed using an electrically-conductive material or a semiconductor having a wider band gap than that of the semiconductor substrate 30. This makes it possible to suppress generation of a dark current at the interface of the semiconductor substrate 30. Examples of the constituent material of the fixed charge layer 21 include hafnium oxide (HfOₓ), aluminum oxide (AlOₓ), zirconium oxide (ZrOₓ), tantalum oxide (TaOₓ), titanium oxide (TiOₓ), lanthanum oxide (LaOₓ), praseodymium oxide (PrOₓ), cerium oxide (CeOₓ), neodymium oxide (NdOₓ), promethium oxide (PmOₓ), samarium oxide (SmOₓ), europium oxide (EuOₓ), gadolinium oxide (GdOₓ), terbium oxide (TbOₓ), dysprosium oxide (DyOₓ), holmium oxide (HoOₓ), thulium oxide (TmOₓ), ytterbium oxide (YbOₓ), lutetium oxide (LuOₓ), yttrium oxide (YOₓ), hafnium nitride (HfNₓ), aluminum nitride (AlNₓ), hafnium oxynitride (HfOₓN_{y}), and aluminum oxynitride (AlOₓN_{y}).

The dielectric layer 22 is provided to prevent light reflection caused by a refractive index difference between the semiconductor substrate 30 and the interlayer insulating layer 23. As a constituent material of the dielectric layer 22, it is preferable to adopt a material having a refractive index between a refractive index of the semiconductor substrate 30 and a refractive index of the interlayer insulating layer 23. Examples of the constituent material of the dielectric layer 22 include SiOₓ, TEOS, SiNₓ, and SiOₓN_{y}.

The interlayer insulating layer 23 is configured by, for example, a monolayer film including one of SiOₓ, SiNₓ and SiOₓN_{y}, or a stacked film including two or more thereof.

The photoelectric conversion regions 32B and 32R are configured by, for example, a PIN (Positive Intrinsic Negative) type photodiode, and each have a p-n junction in a predetermined region of the semiconductor substrate 30. The photoelectric conversion regions 32B and 32R enable light to be dispersed in the vertical direction by utilizing a difference in wavelength regions to be absorbed depending on incidence depth of light in the silicon substrate.

The photoelectric conversion region 32B selectively detects blue light and accumulates signal charge corresponding to blue; the photoelectric conversion region 32B is formed at a depth at which the blue light is able to be efficiently subjected to photoelectric conversion. The photoelectric conversion region 32R selectively detects red light and accumulates signal charge corresponding to red; the photoelectric conversion region 32R is formed at a depth at which the red light is able to be efficiently subjected to photoelectric conversion. It is to be noted that blue (B) is a color corresponding to a wavelength region of 400 nm or more and less than 495 nm, for example, and red (R) is a color corresponding to a wavelength region of 620 nm or more and less than 750 nm, for example. It is sufficient for each of the photoelectric conversion regions 32B and 32R to be able to detect light in a portion or the whole of each wavelength region.

Specifically, as illustrated in FIG. 4, each of the photoelectric conversion region 32B and the photoelectric conversion region 32R includes, for example, a p+ region serving as a hole accumulation layer and an n region serving as an electron accumulation layer (having a p-n-p stacked structure). The n region of the photoelectric conversion region 32B is coupled to the vertical transistor Tr2. The p+ region of the photoelectric conversion region 32B bends along the vertical transistor Tr2, and is linked to the p+ region of the photoelectric conversion region 32R.

The gate insulating layer 33 is configured by, for example, a monolayer film including one of SiOₓ, SiNₓ and SiOₓN_{y}, or a stacked film including two or more thereof.

The through-electrode 34 is provided between the first surface 30S1 and the second surface 30S2 of the semiconductor substrate 30. The through-electrode 34 has a function as a connector for the photoelectric conversion section 10 and a gate Gamp of the amplifier transistor AMP as well as the floating diffusion FD1, and serves as a transmission path for the electric charge generated by the photoelectric conversion section 10. A reset gate Grst of the reset transistor RST is disposed next to the floating diffusion FD1 (one source/drain region 36B of the reset transistor RST). This enables the reset transistor RST to reset the electric charge accumulated in the floating diffusion FD1.

An upper end of the through-electrode 34 is coupled to the readout electrode 11A via, for example, the pad section 39A, an upper first contact 24A, a pad electrode 38B, and the upper second contact 24B provided in the interlayer insulating layer 23. The lower end of the through-electrode 34 is coupled to the coupling section 41A in the wiring layer 41, and the coupling section 41A and the gate Gamp of the amplifier transistor AMP are coupled to each other via a lower first contact 45. The coupling section 41A and the floating diffusion FD1 (region 36B) are coupled to each other via the lower second contact 46, for example.

The upper first contact 24A, the upper second contact 24B, the upper third contact 24C, the pad sections 39A, 39B, and 39C, the wiring layers 41, 42, and 43, the lower first contact 45, the lower second contact 46, and a gate wiring layer 47 may be formed using a doped silicon material such as PDAS (Phosphorus Doped Amorphous Silicon) or a metal material such as Al, W, Ti, Co, Hf, or Ta.

The insulating layer 44 is configured by, for example, a monolayer film including one of SiOₓ, SiNₓ or SiOₓN_{y}, or a stacked film including two or more thereof.

The protective layer 51 and the on-chip lens 52L are configured by a material having light transmissivity, and are configured by, for example, a monolayer film including one of SiOₓ, SiNₓ or SiOₓN_{y}, or a stacked film including two or more thereof. The protective layer 51 has a thickness of, for example, 100 nm or more and 30000 nm or less.

For example, the light-blocking film 53 is provided to cover a region of a readout electrode 21A in direct contact with the semiconductor layer 17 without covering at least the accumulation electrode 11B. The light-blocking film 53 may be formed using, for example, W, Al, an alloy of Al and Cu, or the like.

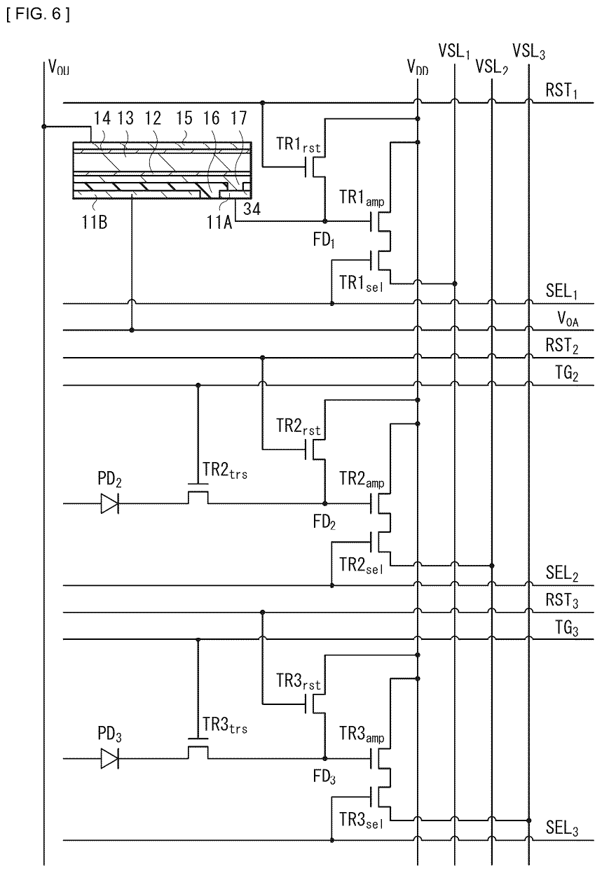

FIG. 6 is an equivalent circuit diagram of the imaging element 1A illustrated in FIG. 4. FIG. 7 schematically illustrates an arrangement of transistors constituting a controller and the lower electrode 11 of the imaging element 1A illustrated in FIG. 4.

The reset transistor RST (a reset transistor TR1rst) resets electric charge transferred from the photoelectric conversion section 10 to the floating diffusion FD1, and is configured by a MOS transistor, for example. Specifically, the reset transistor TR1rst is configured by the reset gate Grst, a channel formation region 36A, and source/drain regions 36B and 36C. The reset gate Grst is coupled to a reset line RST1. The one source/drain region 36B of the reset transistor TR1rst also serves as the floating diffusion FD1. The other source/drain region 36C constituting the reset transistor TR1rst is coupled to a power supply line VDD.

The amplifier transistor AMP is a modulation element that modulates, to a voltage, the amount of electric charge generated by the photoelectric conversion section 10, and is configured by a MOS transistor, for example. Specifically, the amplifier transistor AMP is configured by the gate Gamp, a channel formation region 35A, and source/drain regions 35B and 35C. The gate Gamp is coupled to the readout electrode 11A and the one source/drain region 36B (floating diffusion FD1) of the reset transistor TR1rst via the lower first contact 45, the coupling section 41A, the lower second contact 46, the through-electrode 34, and the like. In addition, the one source/drain region 35B shares a region with the other source/drain region 36C constituting the reset transistor TR1rst, and is coupled to the power supply line VDD.

A selection transistor SEL (a selection transistor TR1sel) is configured by a gate Gsel, a channel formation region 34A, and source/drain regions 34B and 34C. The gate Gsel is coupled to a selection line SEL1. The one source/drain region 34B shares a region with the other source/drain region 35C constituting the amplifier transistor AMP, and the other source/drain region 34C is coupled to a signal line (data output line) VSL1.

The transfer transistor TR2 (a transfer transistor TR2trs) is provided to transfer, to the floating diffusion FD2, signal charge corresponding to blue that has been generated and accumulated in the photoelectric conversion region 32B. The photoelectric conversion region 32B is formed at a deep position from the second surface 30S2 of the semiconductor substrate 30, and it is thus preferable that the transfer transistor TR2trs of the photoelectric conversion region 32B be configured by a vertical transistor. The transfer transistor TR2trs is coupled to a transfer gate line TG2. The floating diffusion FD2 is provided in the region 37C near a gate Gtrs2 of the transfer transistor TR2trs. The electric charge accumulated in the photoelectric conversion region 32B is read to the floating diffusion FD2 via a transfer channel formed along the gate Gtrs2.

The transfer transistor TR3 (a transfer transistor TR3trs) is provided to transfer, to the floating diffusion FD3, signal charge corresponding to red that has been generated and accumulated in the photoelectric conversion region 32R. The transfer transistor TR3 (transfer transistor TR3trs) is configured by, for example, a MOS transistor. The transfer transistor TR3trs is coupled to a transfer gate line TG3. The floating diffusion FD3 is provided in a region 38C near a gate Gtrs3 of the transfer transistor TR3trs. The electric charge accumulated in the photoelectric conversion region 32R is read to the floating diffusion FD3 via a transfer channel formed along the gate Gtrs3.

The side of the second surface 30S2 of the semiconductor substrate 30 is further provided with a reset transistor TR2rst, an amplifier transistor TR2amp, and a selection transistor TR2sel constituting the controller of the photoelectric conversion region 32B. Further, there are provided a reset transistor TR3rst, an amplifier transistor TR3amp, and a selection transistor TR3sel constituting the controller of the photoelectric conversion region 32R.

The reset transistor TR2rst is configured by a gate, a channel formation region, and source/drain regions. The gate of the reset transistor TR2rst is coupled to a reset line RST2, and the one source/drain region of the reset transistor TR2rst is coupled to the power supply line VDD. The other source/drain region of the reset transistor TR2rst also serves as the floating diffusion FD2.

The amplifier transistor TR2amp is configured by a gate, a channel formation region, and source/drain regions. The gate is coupled to the other source/drain region (floating diffusion FD2) of the reset transistor TR2rst. The one source/drain region constituting the amplifier transistor TR2amp shares a region with the one source/drain region constituting the reset transistor TR2rst, and is coupled to the power supply line VDD.

The selection transistor TR2sel is configured by a gate, a channel formation region, and source/drain regions. The gate is coupled to a selection line SEL2. The one source/drain region constituting the selection transistor TR2sel shares a region with the other source/drain region constituting the amplifier transistor TR2amp. The other source/drain region constituting the selection transistor TR2sel is coupled to a signal line (data output line) VSL2.

The reset transistor TR3rst is configured by a gate, a channel formation region, and source/drain regions. The gate of the reset transistor TR3rst is coupled to a reset line RST3, and the one source/drain region constituting the reset transistor TR3rst is coupled to the power supply line VDD. The other source/drain region constituting the reset transistor TR3rst also serves as the floating diffusion FD3.

The amplifier transistor TR3amp is configured by a gate, a channel formation region, and source/drain regions. The gate is coupled to the other source/drain region (floating diffusion FD3) constituting the reset transistor TR3rst. The one source/drain region constituting the amplifier transistor TR3amp shares a region with the one source/drain region constituting the reset transistor TR3rst, and is coupled to the power supply line VDD.

The selection transistor TR3sel is configured by a gate, a channel formation region, and source/drain regions. The gate is coupled to a selection line SEL3. The one source/drain region constituting the selection transistor TR3sel shares a region with the other source/drain region constituting the amplifier transistor TR3amp. The other source/drain region constituting the selection transistor TR3sel is coupled to a signal line (data output line) VSL3.

The reset lines RST1, RST2, and RST3, the selection lines SEL1, SEL2, and SEL3, and the transfer gate lines TG2 and TG3 are each coupled to a vertical drive circuit constituting a drive circuit. The signal lines (data output lines) VSL1, VSL2, and VSL3 are coupled to a column signal processing circuit 112 constituting the drive circuit.

### (1-3. Method of Manufacturing Imaging Element)

The imaging element 1A according to the present embodiment may be manufactured, for example, as follows.

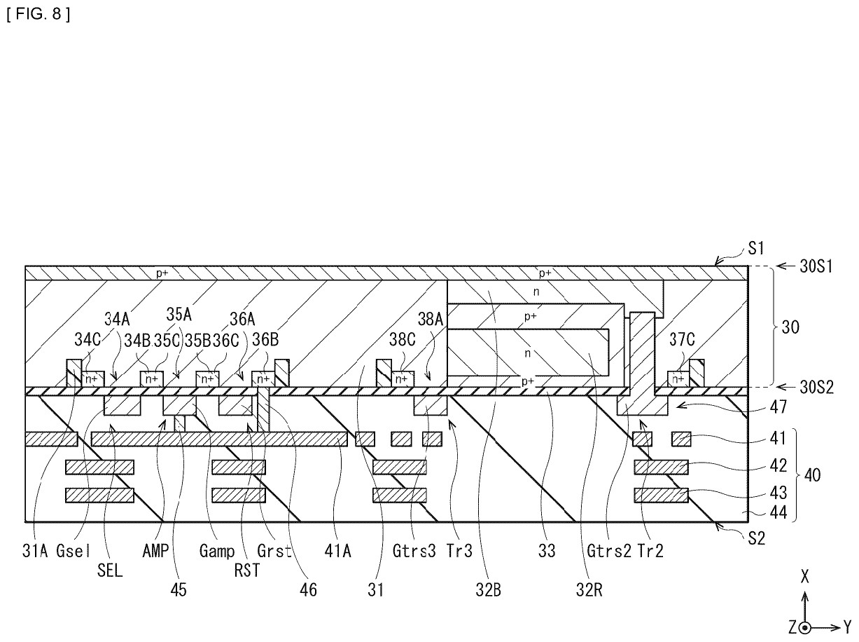

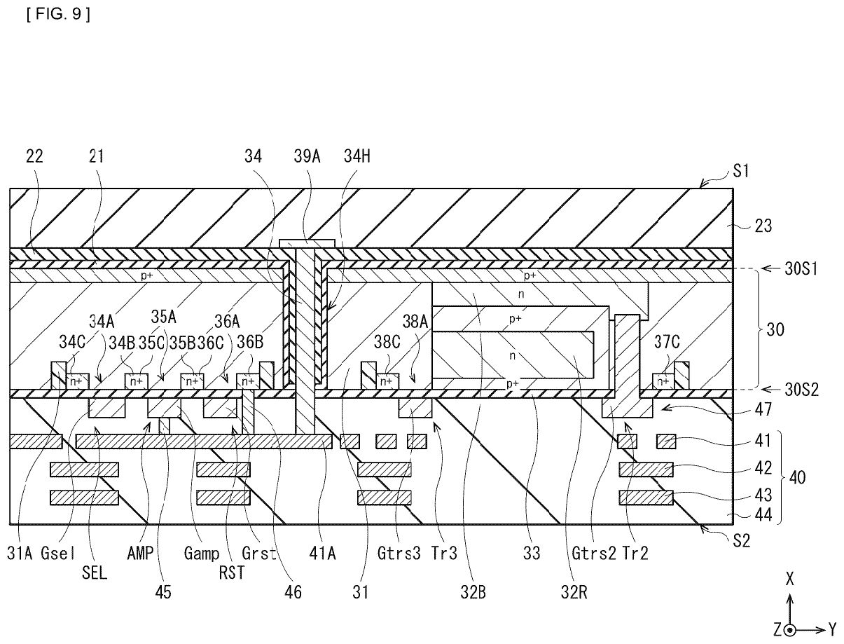

FIGS. 8 to 13 illustrate a method of manufacturing the imaging element 1A in the order of steps. First, as illustrated in FIG. 9, for example, the p-well 31 is formed in the semiconductor substrate 30, and the photoelectric conversion regions 32B and 32R of an n type, for example, are formed in this p-well 31. A p+ region is formed near the first surface 30S1 of the semiconductor substrate 30.

As also illustrated in FIG. 8, for example, n+ regions that serve as the floating diffusions FD1 to FD3 are formed on the second surface 30S2 of the semiconductor substrate 30, and the gate insulating layer 33 and the gate wiring layer 47 are then formed. The gate wiring layer 47 includes the respective gates of the transfer transistor Tr2, the transfer transistor Tr3, the selection transistor SEL, the amplifier transistor AMP, and the reset transistor RST. This forms the transfer transistor Tr2, the transfer transistor Tr3, the selection transistor SEL, the amplifier transistor AMP, and the reset transistor RST. Further, the multilayer wiring layer 40 is formed on the second surface 30S2 of the semiconductor substrate 30. The multilayer wiring layer 40 includes the wiring layers 41 to 43 and the insulating layer 44. The wiring layers 41 to 43 include the lower first contact 45, the lower second contact 46, and the coupling section 41A.

As the base of the semiconductor substrate 30, for example, an SOI (Silicon on Insulator) substrate is used in which the semiconductor substrate 30, an embedded oxide film (unillustrated), and a holding substrate (unillustrated) are stacked. Although not illustrated in FIG. 8, the embedded oxide film and the holding substrate are joined to the first surface 30S1 of the semiconductor substrate 30. After ion implantation, annealing treatment is performed.

Next, a support substrate (unillustrated), another semiconductor base, or the like is joined onto the multilayer wiring layer 40 provided on the side of the second surface 30S2 of the semiconductor substrate 30, and the substrate is turned upside down. Subsequently, the semiconductor substrate 30 is separated from the embedded oxide film and the holding substrate of the SOI substrate to expose the first surface 30S1 of the semiconductor substrate 30. The above-described steps may be performed with a technique used in a normal CMOS process such as ion implantation and CVD (Chemical Vapor Deposition) methods.

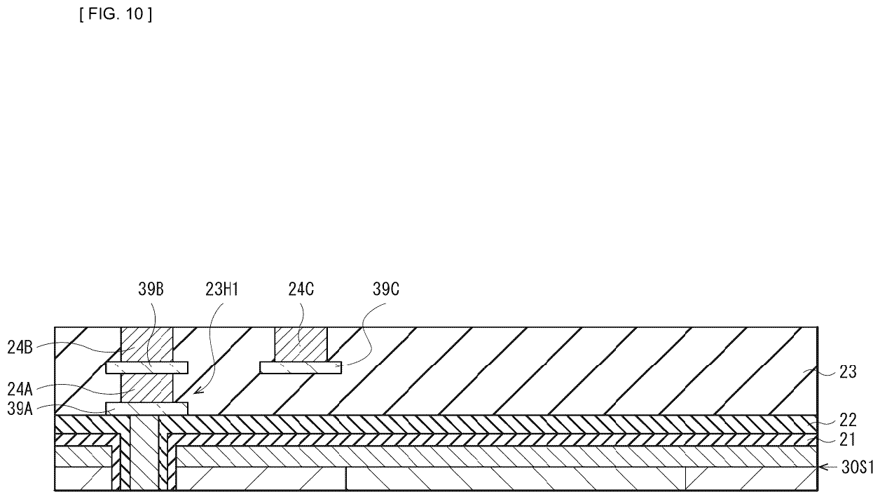

Next, as illustrated in FIG. 9, the semiconductor substrate 30 is worked from the side of the first surface 30S1, for example, by dry etching to form, for example, an annular opening 34H. As for a depth, the opening 34H penetrates from the first surface 30S1 to the second surface 30S2 of the semiconductor substrate 30, and reaches, for example, the coupling section 41A, as illustrated in FIG. 10.

Subsequently, for example, the negative fixed charge layer 21 and the dielectric layer 22 are formed in order on the first surface 30S1 of the semiconductor substrate 30 and on a side surface of the opening 34H. The fixed charge layer 21 may be formed by forming an HfOₓ film using an atomic layer deposition method (ALD method), for example. The dielectric layer 22 may be formed by forming an SiOₓ film using a plasma CVD method, for example. Next, for example, the pad section 39A is formed at a predetermined position on the dielectric layer 22. In the pad section 39A, a barrier metal including a stacked film (Ti/TiN film) of titanium and titanium nitride and a W film are stacked. Thereafter, the interlayer insulating layer 23 is formed on the dielectric layer 22 and the pad section 39A, and a surface of the interlayer insulating layer 23 is planarized using a CMP (Chemical Mechanical Polishing) method.

Subsequently, as illustrated in FIG. 10, an opening 23H1 is formed on the pad section 39A, and then an electrically-conductive material such as Al, for example, is embedded in the opening 23H1 to form the upper first contact 24A. Next, as illustrated in FIG. 10, in the same manner as the pad section 39A, after the pad sections 39B and 39C, the interlayer insulating layer 23, the upper second contact 24B, and the upper third contact 24C are formed in order.

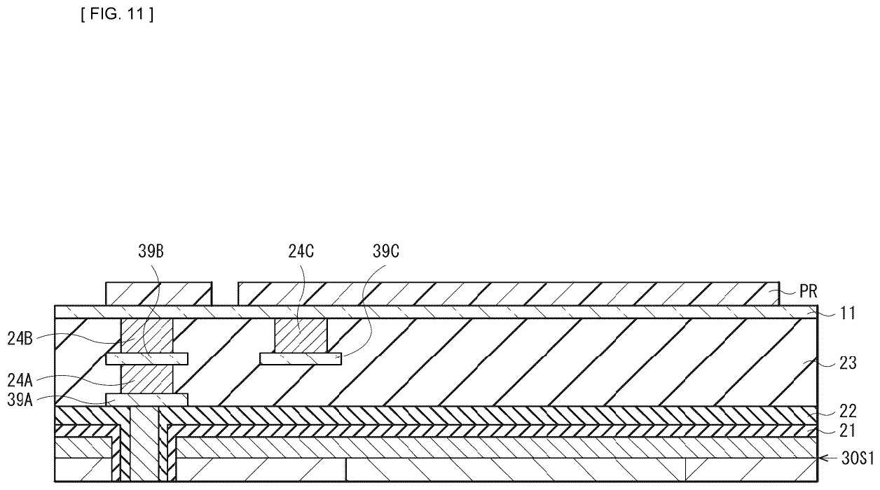

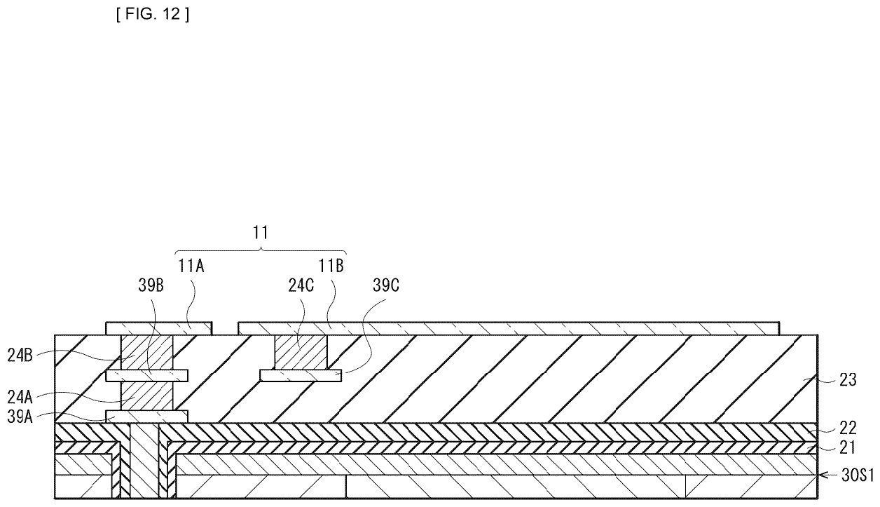

Subsequently, as illustrated in FIG. 11, for example, an electrically-conductive film 11X is formed on the interlayer insulating layer 23 by a sputtering method, and is then patterned using a photolithography technique. Specifically, a photoresist PR is formed at a predetermined position of the electrically-conductive film 11X, and then dry etching or wet etching is used to work the electrically-conductive film 11X. Thereafter, the photoresist PR is removed to thereby form the readout electrode 11A and the accumulation electrode 11B, as illustrated in FIG. 12.

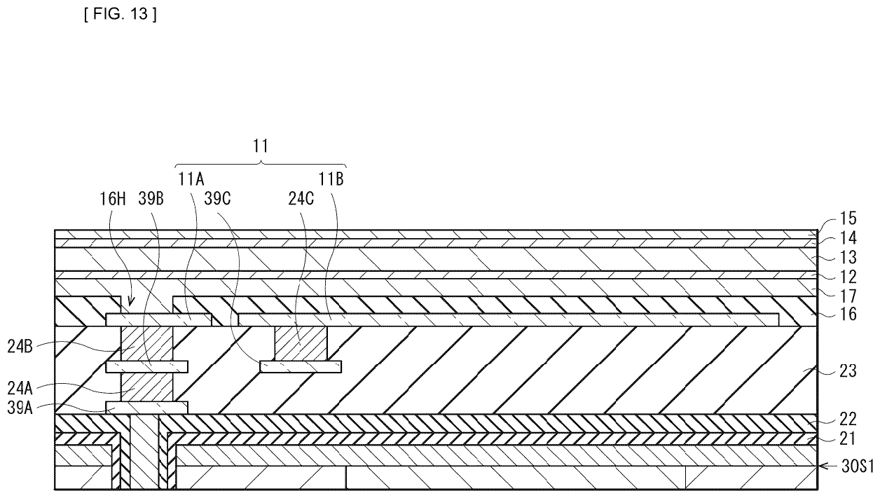

Next, as illustrated in FIG. 13, the insulating layer 16, the semiconductor layer 17, the n-buffer layer 12, the photoelectric conversion layer 13, the p-buffer layer 14, and the upper electrode 15 are formed in order. As for the insulating layer 16, for example, an SiOₓ film is formed using the ALD method, and then a surface of the insulating layer 16 is planarized using the CMP method. Thereafter, the opening 16H is formed on the readout electrode 11A using the wet etching, for example. The semiconductor layer 17 may be formed using the sputtering method, for example. The n-buffer layer 12, the photoelectric conversion layer 13, and the p-buffer layer 14 are formed using a vacuum deposition method, for example. The upper electrode 15 is formed using the sputtering method, for example, in the same manner as for the lower electrode 11. Finally, the protective layer 51, the light-blocking film 53, and the on-chip lens 52L are disposed on the upper electrode 15. As described above, the imaging element 1A illustrated in FIG. 4 is completed.

It is to be noted that, as for the n-buffer layer 12, the photoelectric conversion layer 13, and the p-buffer layer 14, it is desirable that the layers be continuously formed in a vacuum step (by a vacuum-consistent process). In addition, organic layers such as the n-buffer layer 12, the photoelectric conversion layer 13, and the p-buffer layer 14 as well as electrically-conductive films such as the lower electrode 11 and the upper electrode 15 may be formed using a dry film formation method or a wet film formation method. Examples of the dry film formation method include, in addition to the vacuum deposition method using resistive heating or high-frequency heating, an electron-beam (EB) deposition method, various sputtering methods (a magnetron sputtering method, an RF-DC coupled bias sputtering method, an ECR sputtering method, a facing-target sputtering method, and a high-frequency sputtering method), an ion plating method, a laser ablation method, a molecular beam epitaxy method, and a laser transfer method. Other examples of the dry film formation method include chemical vapor deposition methods such as a plasma CVD method, a thermal CVD method, an MOCVD method, and a photo CVD method. Examples of the wet film formation method include a spin coating method, an inkjet method, a spray coating method, a stamp method, a microcontact printing method, a flexographic printing method, an offset printing method, a gravure printing method, and a dipping method.

For patterning, in addition to the photolithography technique, chemical etching such as shadow mask and laser transfer as well as physical etching using ultraviolet rays, laser, or the like may be used. As a planarization technique, in addition to the CMP method, a laser planarization method, a reflow method, or the like may be used.

### (1-4. Signal Acquisition Operation in Imaging Element)

When light enters the photoelectric conversion section 10 via the on-chip lens 52L in the imaging element 1A, the light passes through the photoelectric conversion section 10 and the photoelectric conversion regions 32B and 32R in this order. While the light passes through the photoelectric conversion section 10 and the photoelectric conversion regions 32B and 32R, the light is photoelectrically converted for each of color light beams of green, blue, and red. The following describes operations of acquiring signals of the respective colors.

### (Acquisition of Green Color Signal by Photoelectric Conversion Section 10)

First, green light (G) of the light beams having entered the imaging element 1A is selectively detected (absorbed) and photoelectrically converted by the photoelectric conversion section 10.

The photoelectric conversion section 10 is coupled to the gate Gamp of the amplifier transistor AMP and the floating diffusion FD1 via the through-electrode 34. Thus, electrons of excitons generated by the photoelectric conversion section 10 are taken out from the side of the lower electrode 11, transferred to the side of the second surface 30S2 of the semiconductor substrate 30 via the through-electrode 34, and accumulated in the floating diffusion FD1. At the same time, the amplifier transistor AMP modulates the amount of electric charge generated by the photoelectric conversion section 10 to a voltage.

In addition, the reset gate Grst of the reset transistor RST is disposed next to the floating diffusion FD1. This allows the reset transistor RST to reset the electric charge accumulated in the floating diffusion FD1.

The photoelectric conversion section 10 is coupled not only to the amplifier transistor AMP, but also to the floating diffusion FD1 via the through-electrode 34, thus enabling the reset transistor RST to easily reset the electric charge accumulated in the floating diffusion FD1.

In contrast, in a case where the through-electrode 34 and the floating diffusion FD1 are not coupled to each other, it is difficult to reset the electric charge accumulated in the floating diffusion FD1, thus causing a large voltage to be applied to pull out the electric charge to the side of the upper electrode 15. The photoelectric conversion layer 24 may therefore be possibly damaged. In addition, a structure that enables resetting in a short period of time leads to an increase in dark noises, resulting in a trade-off. This structure is thus difficult.

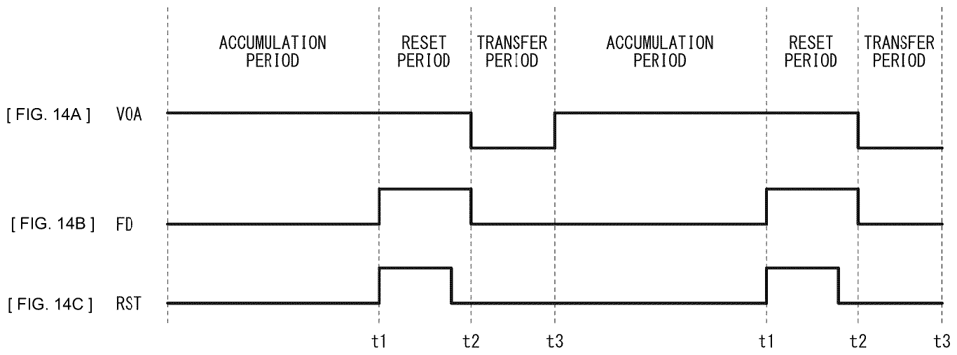

FIG. 14 illustrates an operation example of the imaging element 1A. (A) illustrates the potential at the accumulation electrode 11B, (B) illustrates the potential at the floating diffusion FD1 (readout electrode 11A), and (C) illustrates the potential at the gate (Gsel) of the reset transistor TR1rst. In the imaging element 1A, respective voltages are applied individually to the readout electrode 11A and the accumulation electrode 11B.

In the imaging element 1A, the drive circuit applies a potential V1 to the readout electrode 11A and applies a potential V2 to the accumulation electrode 11B in an accumulation period. Here, it is assumed that the potentials V1 and V2 satisfy V2>V1. This allows electric charge (signal charge: electrons) generated through photoelectric conversion to be drawn to the accumulation electrode 11B and to be accumulated in a region of the semiconductor layer 17 opposed to the accumulation electrode 11B (accumulation period). Incidentally, the value of the potential in the region of the semiconductor layer 17 opposed to the accumulation electrode 11B becomes more negative with the passage of time of photoelectric conversion. It is to be noted that holes are sent from the upper electrode 15 to the drive circuit.

In the imaging element 1A, a reset operation is performed in the latter half of the accumulation period. Specifically, at a timing t1, a scanning section changes the voltage of a reset signal RST from a low level to a high level. This brings the reset transistor TR1rst into an ON state in the unit pixel P. As a result, the voltage of the floating diffusion FD1 is set to a power supply voltage, and the voltage of the floating diffusion FD1 is reset (reset period).

After the reset operation is completed, the electric charge is read. Specifically, the drive circuit applies a potential V3 to the readout electrode 11A and applies a potential V4 to the accumulation electrode 11B at a timing t2. Here, it is assumed that the potentials V3 and V4 satisfy V3<V4. This allows the electric charge accumulated in the region corresponding to the accumulation electrode 11B to be read from the readout electrode 11A to the floating diffusion FD1. That is, the electric charge accumulated in the semiconductor layer 17 is read to the controller (transfer period).

The drive circuit applies the potential V1 to the readout electrode 11A and applies the potential V2 to the accumulation electrode 11B again after the readout operation is completed. This allows electric charge generated through photoelectric conversion to be drawn to the accumulation electrode 11B and to be accumulated in the region of the photoelectric conversion layer 24 opposed to the accumulation electrode 11B (accumulation period).

### (Acquisition of Blue Color Signal and Red Color Signal by Photoelectric Conversion Regions 32B and 32R)

Subsequently, the blue light (B) and the red light (R) of the light beams having been transmitted through the photoelectric conversion section 10 are respectively absorbed and photoelectrically converted in order by the photoelectric conversion region 32B and the photoelectric conversion region 32R. In the photoelectric conversion region 32B, electrons corresponding to the incident blue light (B) are accumulated in an n region of the photoelectric conversion region 32B, and the accumulated electrons are transferred to the floating diffusion FD2 by the transfer transistor Tr2. Likewise, in the photoelectric conversion region 32R, electrons corresponding to the incident red light (R) are accumulated in an n region of the photoelectric conversion region 32R, and the accumulated electrons are transferred to the floating diffusion FD3 by the transfer transistor Tr3.

### (1-5. Workings and Effects)

The photoelectric conversion element 10 of the present embodiment is provided, between the lower electrode 11 and the upper electrode 15 disposed to be opposed to each other, with an organic layer having a carrier mobility of 10⁻⁵ cm²/Vs or more and 10⁻² cm²/Vs or less, a carrier lifetime of 0.010 μs or more and 1.0 μs or less, and a carrier range of 10 nm or more and 1 μm or less. This is described below.

As described above, in a typical organic photoelectric conversion element, oxygen is used as a quencher when producing the element to thereby achieve an improvement in light resistance. As a method of mixing oxygen, a method is used that involves forming, as a film, an upper electrode (e.g., an ITO electrode) and then exposing the element to the atmosphere for about one day. However, such a method results in an issue in which oxygen serves as a carrier trap, thus lowering initial characteristics such as the EQE. In addition, there is an issue in which it is difficult to control oxygen as the quencher, thus causing the EQE to be decreased after a light resistance test.

In contrast, in the present embodiment, the organic layer including the photoelectric conversion layer 13, for example, provided between the lower electrode 11 and the upper electrode 15 is configured to have a carrier mobility of 10⁻⁵ cm²/Vs or more and 10⁻² cm²/Vs or less, a carrier lifetime of 0.010 μs or more and 1.0 μs or less, and a carrier range of 10 nm or more and 1 μm or less. This suppresses photopolymerization of the electron-transporting material (fullerene), which is a factor of deterioration of light resistance, without using a quencher.

As described above, the initial element characteristics such as the EQE is improved in the photoelectric conversion element 10 of the present embodiment. In addition, the variation in the element characteristics before and after the light resistance test is decreased. This makes it possible to provide the photoelectric conversion element 10 having high light resistance as well as an electronic apparatus such as a photodetector 2002 (e.g., refer to FIGS. 24A and 24B) or the imaging device 100 including the photoelectric conversion element 10.

Next, description is given of Modification Examples 1 to 5 of the present disclosure. It is to be noted that components corresponding to those of the photoelectric conversion element 10 and the imaging element 1A of the foregoing embodiment are denoted by the same reference numerals, and descriptions thereof are omitted.

### 2. MODIFICATION EXAMPLES

### 2-1. Modification Example 1

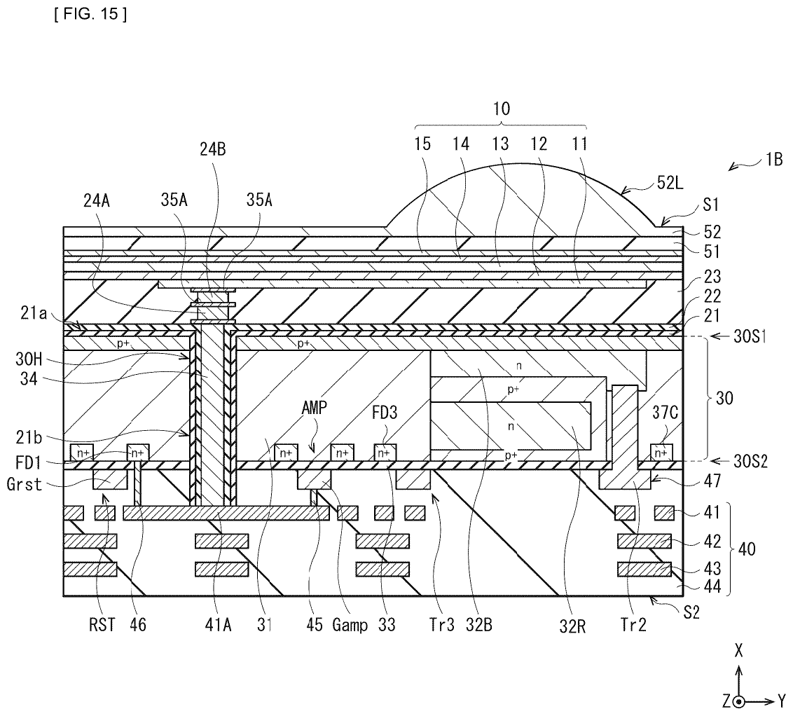

FIG. 15 schematically illustrates a cross-sectional configuration of an imaging element 1B according to Modification Example 1 of the present disclosure. In the same manner as the imaging element 1A of the foregoing embodiment, the imaging element 1B is an imaging element such as a CMOS image sensor used in an electronic apparatus such as a digital still camera or a video camera, for example. The imaging element 1B of the present modification example differs from the foregoing embodiment in that the lower electrode 11 includes one electrode for each unit pixel P.

In the same manner as the imaging element 1A described above, in the imaging element 1B, one photoelectric conversion section 10 and two photoelectric conversion regions 32B and 32R are stacked in the vertical direction for each unit pixel P. The photoelectric conversion section 10 corresponds to the photoelectric conversion element 10 described above, and is provided on a side of a back surface (a first surface 30S1) of the semiconductor substrate 30. The photoelectric conversion regions 32B and 32R are formed to be embedded in the semiconductor substrate 30, and are stacked in the thickness direction of the semiconductor substrate 30.

As described above, the imaging element 1B of the present modification example has configurations similar to those of the imaging element 1A except that the lower electrode 11 of the photoelectric conversion section 10 includes one electrode and that the insulating layer 16 and the semiconductor layer 17 are not provided between the lower electrode 11 and the n-buffer layer 12.

As described above, the configuration of the photoelectric conversion section 10 is not limited to that in the imaging element 1A of the foregoing embodiment; it is possible to achieve effects similar to those of the foregoing embodiment even when the imaging element 1B of the present modification example is employed for the configuration of the photoelectric conversion section 10.

### 2-2. Modification Example 2

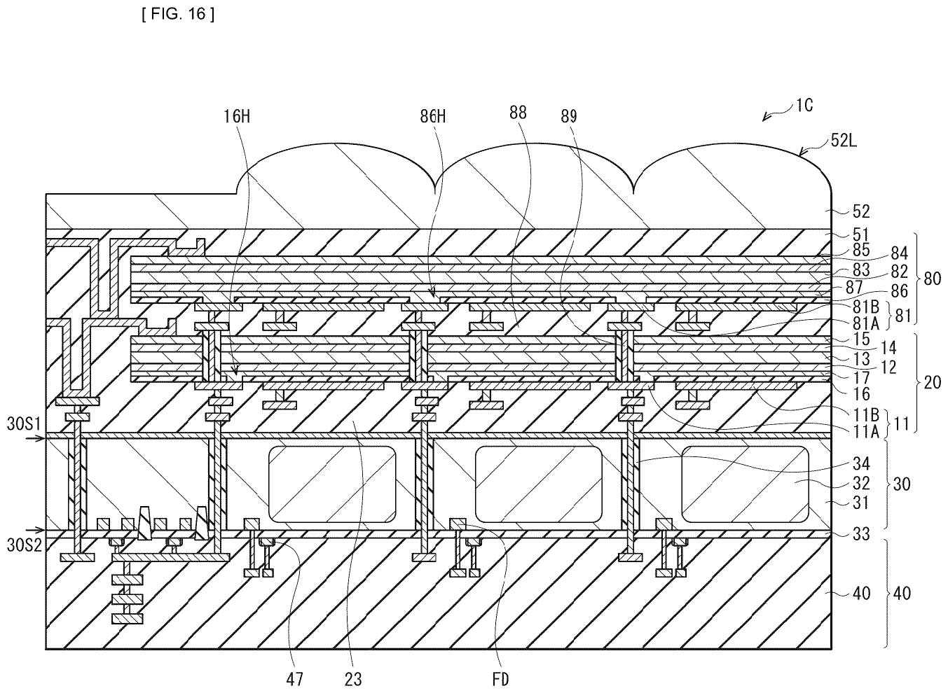

FIG. 16 schematically illustrates a cross-sectional configuration of an imaging element 1C according to Modification Example 2 of the present disclosure. In the same manner as the imaging element 1A of the foregoing embodiment, the imaging element 1C is an imaging element such as a CMOS image sensor used in an electronic apparatus such as a digital still camera or a video camera, for example. In the imaging element 1C of the present modification example, two photoelectric conversion sections 10 and 80 and one photoelectric conversion region 32 are stacked in the vertical direction.

The photoelectric conversion sections 10 and 80 and the photoelectric conversion region 32 selectively detect light beams in wavelength regions different from each other to perform photoelectric conversion. For example, the photoelectric conversion section 10 acquires a color signal of green (G). For example, the photoelectric conversion section 80 acquires a color signal of blue (B). For example, the photoelectric conversion region 32 acquires a color signal of red (R). This enables the imaging element 1C to acquire a plurality of types of color signals in one pixel without using a color filter.

The photoelectric conversion sections 10 and 80 have a configuration similar to that of the imaging element 1A of the foregoing embodiment. Specifically, in the photoelectric conversion section 10, the lower electrode 11, the n-buffer layer 12, the photoelectric conversion layer 13, the p-buffer layer 14, and the upper electrode 15 are stacked in this order, in the same manner as the imaging element 1A. The lower electrode 11 includes a plurality of electrodes (e.g., the readout electrode 11A and the accumulation electrode 11B), and the insulating layer 16 and the semiconductor layer 17 are stacked in this order between the lower electrode 11 and the n-buffer layer 12. The readout electrode 11A of the lower electrode 11 is electrically coupled to the semiconductor layer 17 via the opening 16H provided in the insulating layer 16. Also in the photoelectric conversion section 80, there are stacked a lower electrode 81, an n-buffer layer 82, a photoelectric conversion layer 83, a p-buffer layer 84, and an upper electrode 85 in this order, in the same manner as the photoelectric conversion section 10. The lower electrode 81 includes a plurality of electrodes (e.g., a readout electrode 81A and an accumulation electrode 81B), and an insulating layer 86 and a semiconductor layer 87 are stacked in this order between the lower electrode 81 and the n-buffer layer 82. The readout electrode 81A of the lower electrode 81 is electrically coupled to the semiconductor layer 87 via an opening 87H provided in the insulating layer 86. It is to be noted that one or both of the semiconductor layer 17 and the semiconductor layer 87 may be omitted.

A through-electrode 89 is coupled to the readout electrode 81A. The through-electrode 89 penetrates an interlayer insulating layer 88 and the photoelectric conversion section 10, and is electrically coupled to the readout electrode 11A of the photoelectric conversion section 10. Further, the readout electrode 81A is electrically coupled to the floating diffusion FD provided in the semiconductor substrate 30 via through-electrodes 34 and 89, thus enabling electric charge generated in the photoelectric conversion layer 83 to be temporarily accumulated. Further, the readout electrode 81A is electrically coupled to the amplifier transistor AMP or the like provided in the semiconductor substrate 30 via the through-electrodes 34 and 89.

### 2-3. Modification Example 3

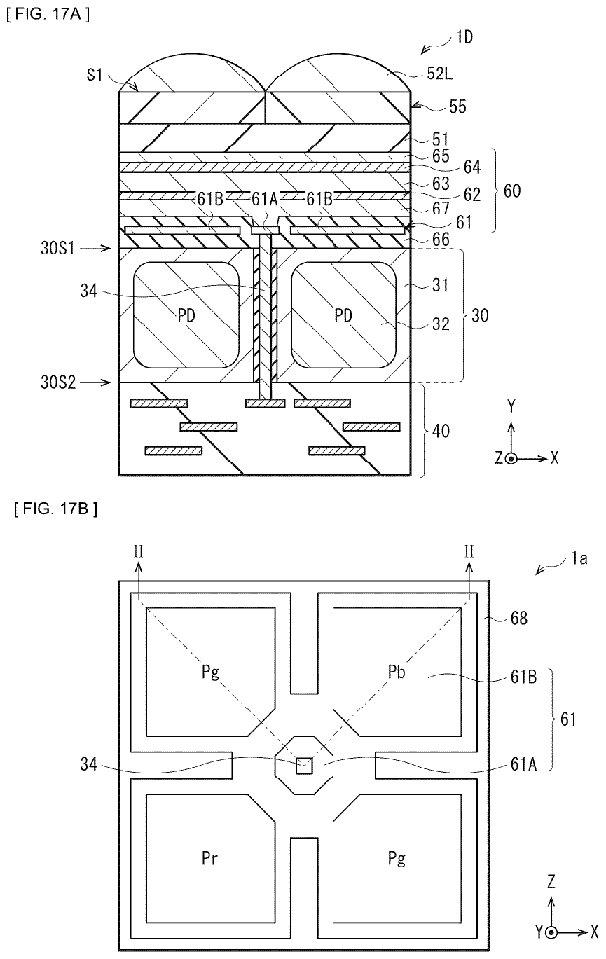

FIG. 17A schematically illustrates a cross-sectional configuration of an imaging element 1D according to Modification Example 3 of the present disclosure. FIG. 17B schematically illustrates an example of a planar configuration of the imaging element 1D illustrated in FIG. 17A, and FIG. 17A illustrates a cross-section along a line II-II illustrated in FIG. 17B. The imaging element 1D is, for example, a stacked imaging element in which the photoelectric conversion region 32 and the photoelectric conversion section 60 are stacked. In the pixel section 100A of the imaging device (e.g., imaging device 100) including the imaging element 1D, the pixel unit 1a including four pixels arranged in two rows×two columns is a repeating unit, for example, as illustrated in FIG. 17B, and the pixel units 1a are repeatedly arranged in array in a row direction and a column direction.

The imaging element 1D of the present modification example is provided with color filters 55 above the photoelectric conversion section 60 (light incident side S1) for the respective unit pixels P. The respective color filters 55 selectively transmit red light (R), green light (G), and blue light (B). Specifically, in the pixel unit 1a including the four pixels arranged in two rows×two columns, two color filters each of which selectively transmits green light (G) are disposed on a diagonal line, and color filters that selectively transmit red light (R) and blue light (B) are arranged one by one on the orthogonal diagonal line. Unit pixels (Pr, Pg, and Pb) provided with the respective color filters each detect the corresponding color light, for example, in the photoelectric conversion section 60. That is, the respective pixels (Pr, Pg, and Pb) that detect red light (R), green light (G), and blue light (B) have a Bayer arrangement in the pixel section 100A.

The photoelectric conversion section 60 absorbs light corresponding to a portion or the whole of a wavelength of a visible light region of 400 nm or more and less than 750 nm, for example, to generate excitons (electron-hole pairs). In the photoelectric conversion section 60, there are stacked a lower electrode 61, an insulating layer (an interlayer insulating layer 66), a semiconductor layer 67, an n-buffer layer 62, a photoelectric conversion layer 63, a p-buffer layer 64, and an upper electrode 65 in this order. The lower electrode 61, the interlayer insulating layer 66, the semiconductor layer 67, the n-buffer layer 62, the photoelectric conversion layer 63, the p-buffer layer 64, and the upper electrode 65 respectively have configurations similar to those of the lower electrode 11, the insulating layer 16, the semiconductor layer 17, the n-buffer layer 12, the photoelectric conversion layer 13, the p-buffer layer 14, and the upper electrode 15 of the imaging element 1A in the foregoing embodiment. The lower electrode 61 includes, for example, a readout electrode 61A and an accumulation electrode 61B independent of each other, and the readout electrode 61A is shared by four pixels, for example. It is to be noted that the semiconductor layer 67 may be omitted.

The photoelectric conversion region 32 detects an infrared light region of 750 nm or more and 1300 nm or less, for example.

In the imaging element 1D, light beams (red light (R), green light (G), and blue light (B)) of the visible light region, among the light beams transmitted through the color filters 55, are absorbed by each photoelectric conversion section 60 of the unit pixels (Pr, Pg, and Pb) provided with the respective color filters. The other light, e.g., light (infrared light (IR)) in an infrared light region (e.g., 750 nm or more and 1000 nm or less) is transmitted through the photoelectric conversion section 60. This infrared light (IR) transmitted through the photoelectric conversion section 60 is detected by the photoelectric conversion region 32 of each of the unit pixels Pr, Pg, and Pb. Each of the unit pixels Pr, Pg, and Pb generates signal charge corresponding to the infrared light (IR). That is, the imaging device 100 including the imaging element 1D is able to simultaneously generate both a visible light image and an infrared light image.

In addition, in the imaging device 100 including the imaging element 1D is able to acquire the visible light image and the infrared light image at the same position in an X-Z in-plane direction. It is therefore possible to achieve higher integration in the X-Z in-plane direction.

### 2-4. Modification Example 4

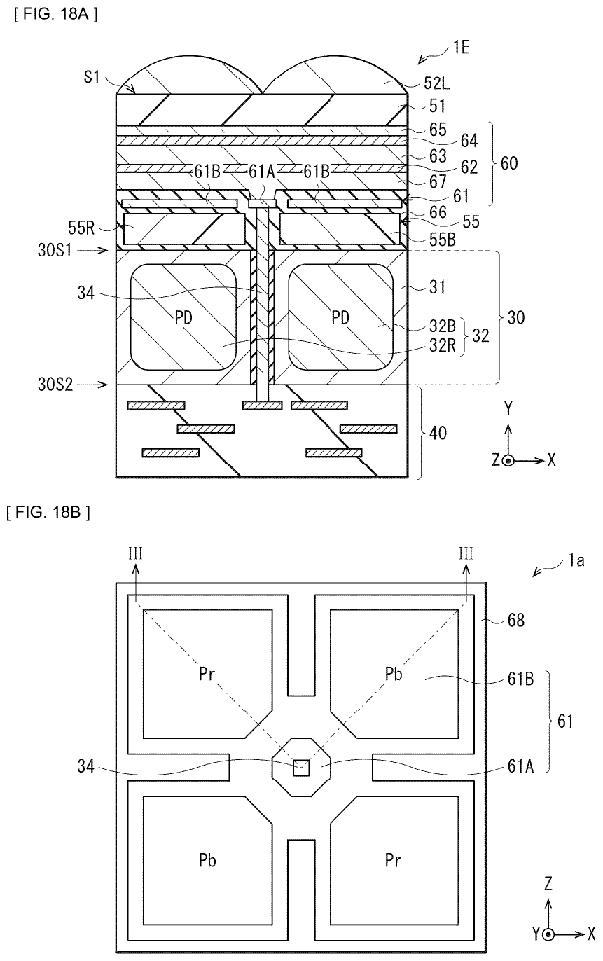

FIG. 18A schematically illustrates a cross-sectional configuration of an imaging element 1E of Modification Example 4 of the present disclosure. FIG. 18B schematically illustrates an example of a planar configuration of the imaging element 1E illustrated in FIG. 18A. FIG. 18A illustrates a cross-section along a line III-III illustrated in FIG. 18B. In the foregoing Modification Example 3, the example has been described in which the color filters 55 are provided above the photoelectric conversion section 60 (light incident side S1), but the color filters 55 may be provided between the photoelectric conversion region 32 and the photoelectric conversion section 60, for example, as illustrated in FIG. 18A.

For example, the imaging element 1E has a configuration in which color filters (color filters 55R) each of which selectively transmits at least red light (R) and color filters (color filters 55B) each of which selectively transmits at least blue light (B) are arranged on the respective diagonal lines in the pixel unit 1a. The photoelectric conversion section 60 (photoelectric conversion layer 63) is configured to selectively absorb light having a wavelength corresponding to green light (G), for example. The photoelectric conversion region 32R selectively absorbs light having a wavelength corresponding to red light (R), and the photoelectric conversion region 32B selectively absorbs light having a wavelength corresponding to blue light (B). This enables the photoelectric conversion sections 60 and the respective photoelectric conversion regions 32 (photoelectric conversion regions 32R and 32B) arranged below the color filters 55R and 55B to acquire signals corresponding to red light (R), green light (G), and blue light (B). The imaging element 1E according to the present modification example enables the respective photoelectric conversion sections of R, G, and B to each have a larger area than that of the photoelectric conversion element having a typical Bayer arrangement. This makes it possible to improve the S/N ratio.

### 2-5. Modification Example 5

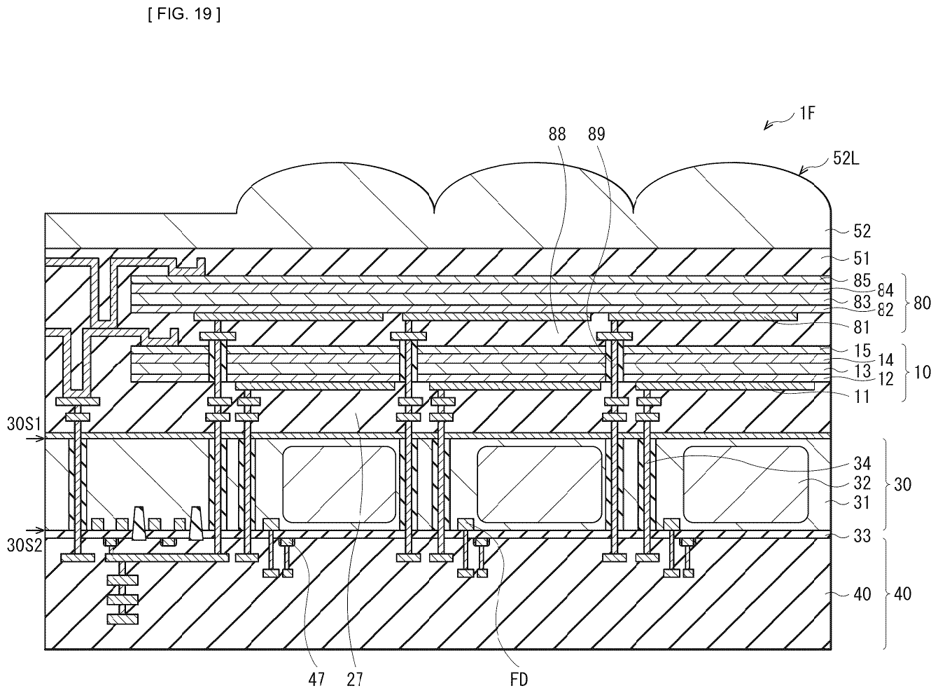

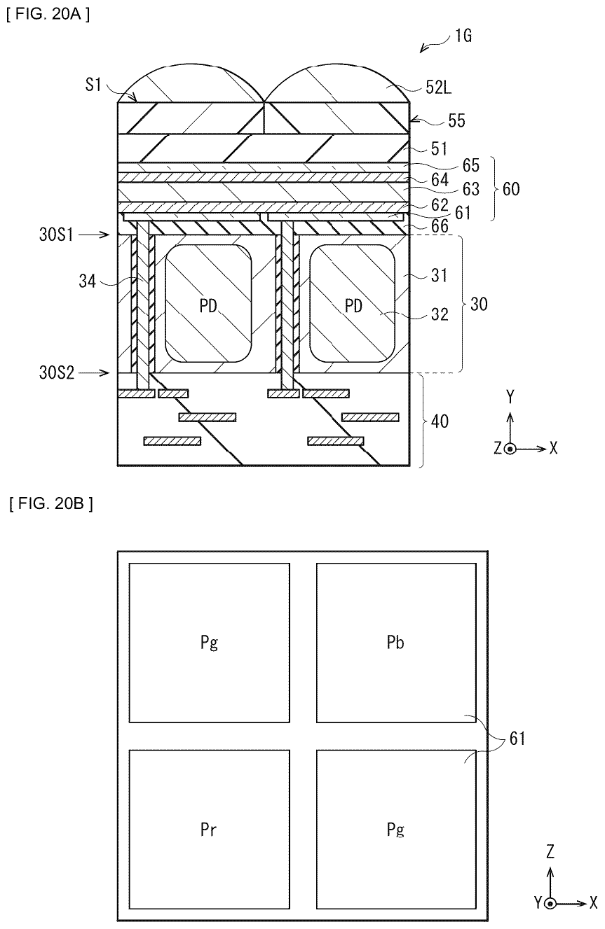

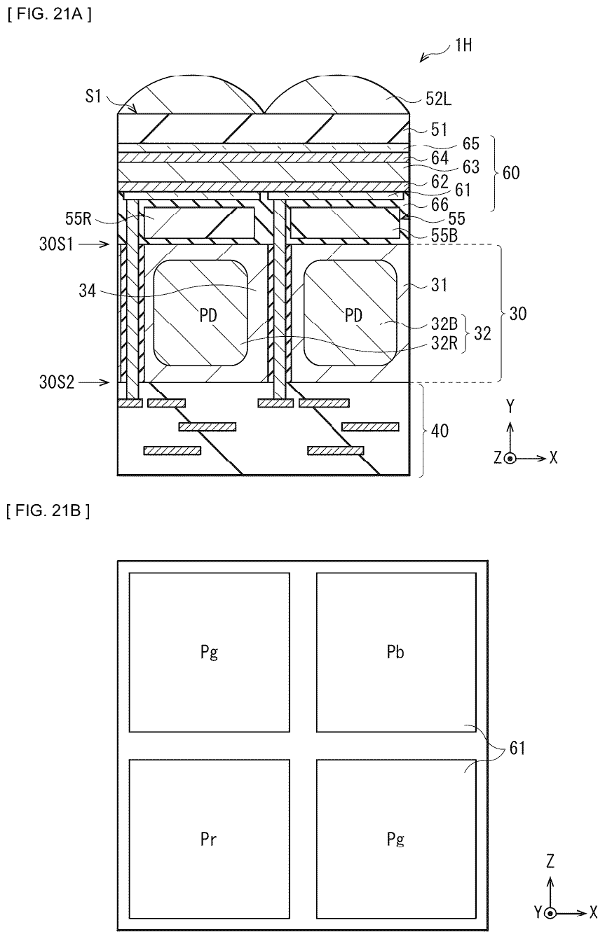

FIG. 19 illustrates another example (an imaging element 1F) of the cross-sectional configuration of the imaging element 1C of Modification Example 2 according to another modification example of the present disclosure. FIG. 20A schematically illustrates another example (an imaging element 1G) of the cross-sectional configuration of the imaging element 1D of Modification Example 3 according to another modification example of the present disclosure. FIG. 20B schematically illustrates an example of a planar configuration of the imaging element 1G illustrated in FIG. 20A. FIG. 21A schematically illustrates another example (an imaging element 1H) of the cross-sectional configuration of the imaging element 1E of Modification Example 4 according to another modification example of the present disclosure. FIG. 21B schematically illustrates an example of a planar configuration of the imaging element 1H illustrated in FIG. 21A.

The foregoing Modification Examples 2 to 4 exemplify the cases where the lower electrodes 11, 61, and 81 constituting the photoelectric conversion sections 60 and 80 respectively include a plurality of electrodes (readout electrodes 11A, 61A, and 81A and accumulation electrodes 11B, 61B, and 81B); however, this is not limitative. In the same manner as the foregoing Modification Example 1, the imaging elements 1C, 1D, and 1E according to Modification Examples 2 to 4 are also applicable to a case where the lower electrode includes one electrode for each unit pixel P, thus making it possible to achieve effects similar to those of the foregoing Modification Examples 2 to 4.

### 3. APPLICATION EXAMPLES

### Application Example 1

FIG. 22 illustrates an example of an overall configuration of an imaging device (imaging device 100) including the imaging element (e.g., imaging element 1A) illustrated in FIG. 4 or other drawings.

The imaging device 100 is, for example, a CMOS image sensor. The imaging device 100 takes in incident light (image light) from a subject via an optical lens system (unillustrated), and converts the amount of incident light formed as an image on an imaging surface into electric signals in units of pixels to output the electric signals as pixel signals. The imaging device 100 includes the pixel section 100A as an imaging area on the semiconductor substrate 30. In addition, the imaging device 100 includes, for example, a vertical drive circuit 111, the column signal processing circuit 112, a horizontal drive circuit 113, an output circuit 114, a control circuit 115, and an input/output terminal 116 in a peripheral region of this pixel section 100A.

The pixel section 100A includes, for example, the plurality of unit pixels P that are two-dimensionally arranged in matrix. The unit pixels P are provided, for example, with a pixel drive line Lread (specifically, a row selection line and a reset control line) for each of pixel rows and provided with a vertical signal line Lsig for each of pixel columns. The pixel drive line Lread transmits drive signals for reading signals from the pixels. One end of the pixel drive line Lread is coupled to an output end of the vertical drive circuit 111 corresponding to each of the rows.

The vertical drive circuit 111 is a pixel drive section that is configured by a shift register, an address decoder, and the like and drives the unit pixels P of the pixel section 100A on a row-by-row basis, for example. Signals outputted from the respective unit pixels P in the pixel rows selectively scanned by the vertical drive circuit 111 are supplied to the column signal processing circuit 112 through the respective vertical signal lines Lsig. The column signal processing circuit 112 is configured by an amplifier, a horizontal selection switch, and the like provided for each of the vertical signal lines Lsig.

The horizontal drive circuit 113 is configured by a shift register, an address decoder, and the like. The horizontal drive circuit 113 drives horizontal selection switches of the column signal processing circuit 112 in order while scanning the horizontal selection switches. The selective scanning by this horizontal drive circuit 113 causes signals of the respective pixels transmitted through the respective vertical signal lines Lsig to be outputted to a horizontal signal line 121 in order and causes the signals to be transmitted to the outside of the semiconductor substrate 30 through the horizontal signal line 121.

The output circuit 114 performs signal processing on signals sequentially supplied from the respective column signal processing circuits 112 via the horizontal signal line 121, and outputs the signals. The output circuit 114 performs, for example, only buffering in some cases, and performs black level adjustment, column variation correction, various kinds of digital signal processing, and the like in other cases.

The circuit portion including the vertical drive circuit 111, the column signal processing circuit 112, the horizontal drive circuit 113, the horizontal signal line 121, and the output circuit 114 may be formed directly on the semiconductor substrate 30, or may be provided on an external control IC. In addition, the circuit portion may be formed in another substrate coupled by a cable or the like.

The control circuit 115 receives a clock supplied from the outside of the semiconductor substrate 30, data for an instruction about an operation mode, and the like and also outputs data such as internal information on the imaging device 100. The control circuit 115 further includes a timing generator that generates various timing signals, and controls driving of the peripheral circuits including the vertical drive circuit 111, the column signal processing circuit 112, the horizontal drive circuit 113, and the like on the basis of the various timing signals generated by the timing generator.

The input/output terminal 116 exchanges signals with the outside.

### Application Example 2

In addition, the above-described imaging device 100 is applicable, for example, to various types of electronic apparatuses including an imaging system such as a digital still camera and a video camera, a mobile phone having an imaging function, or another device having an imaging function.

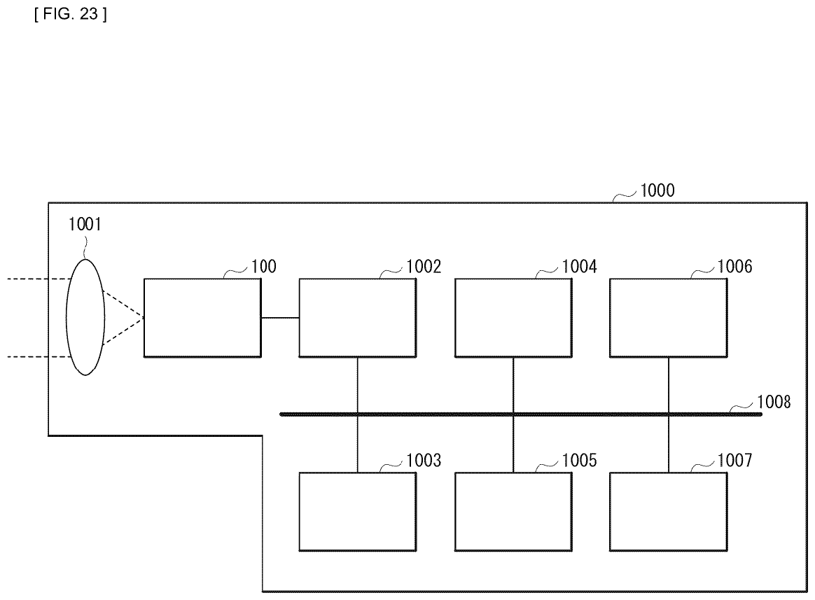

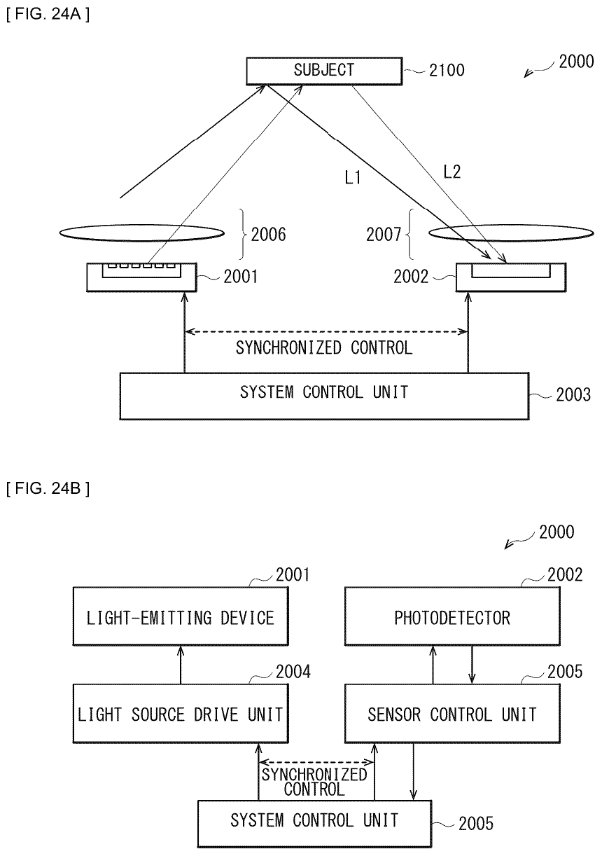

FIG. 23 is a block diagram illustrating an example of a configuration of an electronic apparatus 1000.

As illustrated in FIG. 23, the electronic apparatus 1000 includes an optical system 1001, the imaging device 100, and a DSP (Digital Signal Processor) 1002, and has a configuration in which the DSP 1002, a memory 1003, a display device 1004, a recording device 1005, an operation system 1006, and a power supply system 1007 are coupled together via a bus 1008, thus making it possible to capture a still image and a moving image.

The optical system 1001 includes one or a plurality of lenses, and takes in incident light (image light) from a subject to form an image on an imaging surface of the imaging device 100.

The above-described imaging device 100 is applied as the imaging device 100. The imaging device 100 converts the amount of incident light formed as an image on the imaging surface by the optical system 1001 into electric signals in units of pixels, and supplies the DSP 1002 with the electric signals as pixel signals.

The DSP 1002 performs various types of signal processing on the signals from the imaging device 100 to acquire an image, and causes the memory 1003 to temporarily store data on the image. The image data stored in the memory 1003 is recorded in the recording device 1005, or is supplied to the display device 1004 to display the image. In addition, the operation system 1006 receives various operations by the user, and supplies operation signals to the respective blocks of the electronic apparatus 1000. The power supply system 1007 supplies electric power required to drive the respective blocks of the electronic apparatus 1000.

### Application Example 3

FIG. 24A schematically illustrates an example of an overall configuration of a photodetection system 2000 including the imaging device 100. FIG. 24B illustrates an example of a circuit configuration of the photodetection system 2000. The photodetection system 2000 includes a light-emitting device 2001 as a light source unit that emits infrared light L2 and a photodetector 2002 as a light-receiving unit with a photoelectric conversion element. The above-described imaging device 100 may be used as the photodetector 2002. The photodetection system 2000 may further include a system control unit 2003, a light source drive unit 2004, a sensor control unit 2005, a light source side optical system 2006, and a camera side optical system 2007.

The photodetector 2002 is able to detect light L1 and light L2. The light L1 is reflected light of ambient light from the outside reflected by a subject (measurement target) 2100 (FIG. 24A). The light L2 is light reflected by the subject 2100 after having been emitted by the light-emitting device 2001. The light L1 is, for example, visible light, and the light L2 is, for example, infrared light. The light L1 is detectable at the photoelectric conversion section in the photodetector 2002, and the light L2 is detectable at a photoelectric conversion region in the photodetector 2002. It is possible to acquire image information on the subject 2100 from the light L1 and to acquire information on a distance between the subject 2100 and the photodetection system 2000 from the light L2. For example, the photodetection system 2000 can be mounted on an electronic apparatus such as a smartphone or on a mobile body such as a car. The light-emitting device 2001 can be configured by, for example, a semiconductor laser, a surface-emitting semiconductor laser, or a vertical resonator surface-emitting laser (VCSEL). An iTOF method can be employed as a method for the photodetector 2002 to detect the light L2 emitted from the light-emitting device 2001; however, this is not limitative. In the iTOF method, the photoelectric conversion section is able to measure a distance to the subject 2100 by time of flight of light (Time-of-Flight; TOF), for example. As a method for the photodetector 2002 to detect the light L2 emitted from the light-emitting device 2001, it is possible to adopt, for example, a structured light method or a stereovision method. For example, in the structured light method, light having a predetermined pattern is projected on the subject 2100, and distortion of the pattern is analyzed, thereby making it possible to measure the distance between the photodetection system 2000 and the subject 2100. In addition, in the stereovision method, for example, two or more cameras are used to acquire two or more images of the subject 2100 viewed from two or more different viewpoints, thereby making it possible to measure the distance between the photodetection system 2000 and the subject. It is to be noted that it is possible for the system control unit 2003 to synchronously control the light-emitting device 2001 and the photodetector 2002.

### 4. PRACTICAL APPLICATION EXAMPLES

### (Example of Practical Application to Endoscopic Surgery System)

The technology according to an embodiment of the present disclosure (present technology) is applicable to various products. For example, the technology according to an embodiment of the present disclosure may be applied to an endoscopic surgery system.

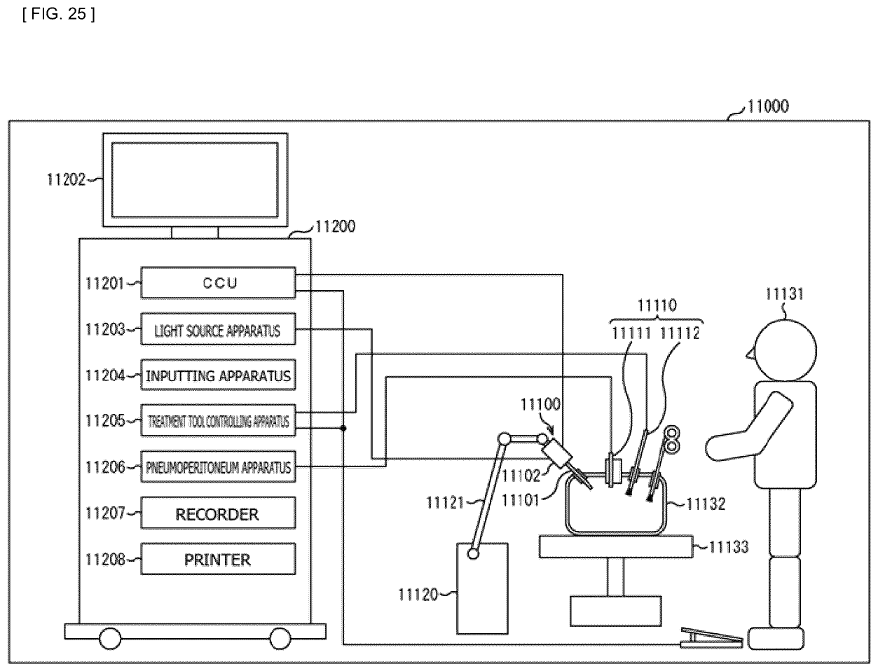

FIG. 25 is a view depicting an example of a schematic configuration of an endoscopic surgery system to which the technology according to an embodiment of the present disclosure (present technology) can be applied.

In FIG. 25, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

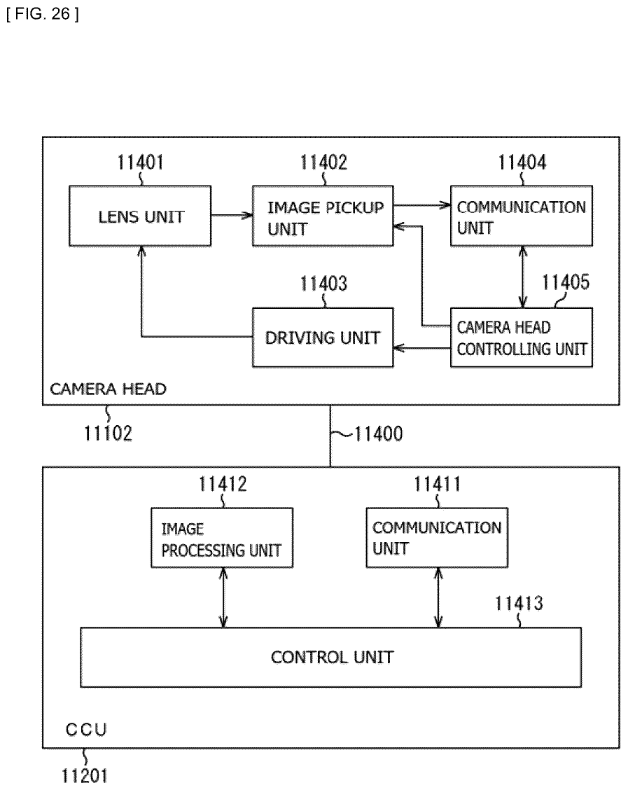

FIG. 26 is a block diagram depicting an example of a functional configuration of the camera head 11102 and the CCU 11201 depicted in FIG. 25.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given above of one example of the endoscopic surgery system, to which the technology according to an embodiment of the present disclosure is applicable. The technology according to an embodiment of the present disclosure is applicable to, for example, the image pickup unit 11402 of the configurations described above. Applying the technology according to an embodiment of the present disclosure to the image pickup unit 11402 makes it possible to improve detection accuracy.

It is to be noted that although the endoscopic surgery system has been described as an example here, the technology according to an embodiment of the present disclosure may also be applied to, for example, a microscopic surgery system, and the like.

### (Example of Practical Application to Mobile Body)

The technology according to an embodiment of the present disclosure (present technology) is applicable to various products. For example, the technology according to an embodiment of the present disclosure may be achieved in the form of an apparatus to be mounted to a mobile body of any kind. Non-limiting examples of the mobile body may include an automobile, an electric vehicle, a hybrid electric vehicle, a motorcycle, a bicycle, any personal mobility device, an airplane, an unmanned aerial vehicle (drone), a vessel, a robot, a construction machine, and an agricultural machine (tractor).

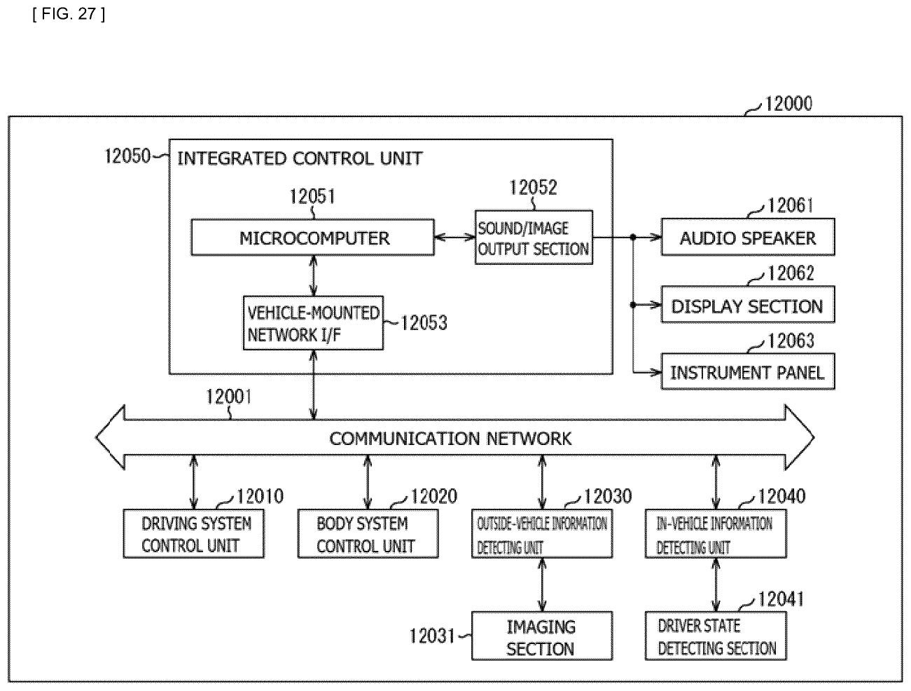

FIG. 27 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 27, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 27, an audio speaker 12061, a display section 12062, and an instrument panel 12063 are illustrated as the output device. The display section 12062 may, for example, include at least one of an on-board display and a head-up display.

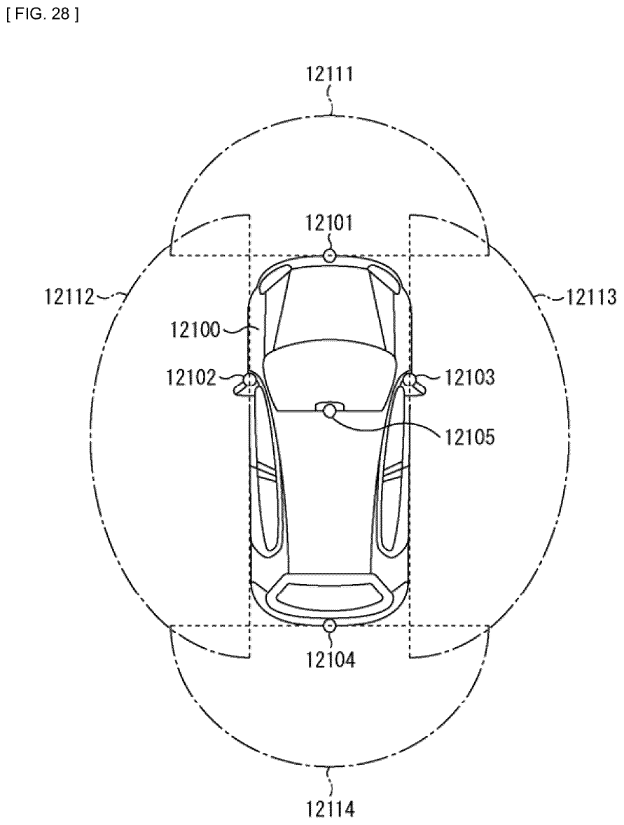

FIG. 28 is a diagram depicting an example of the installation position of the imaging section 12031.

In FIG. 28, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 28 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of one example of the mobile body control system, to which the technology according to an embodiment of the present disclosure may be applied. The technology according to an embodiment of the present disclosure may be applied to the imaging section 12031 among components of the configuration described above. Specifically, the imaging element (e.g., imaging element 1A) according to any of the foregoing embodiments and modification examples thereof is applicable to the imaging section 12031. The application of the technology according to an embodiment of the present disclosure to the imaging section 12031 allows for a high-definition captured image with less noise, thus making it possible to perform highly accurate control utilizing the captured image in the mobile body control system.

### 5. EXAMPLES

Next, description is given of Examples of the present disclosure.

### Experimental Example 1

First, an ITO film having a thickness of 50 nm was deposited on a silicon substrate using a sputtering apparatus. The film was worked by photolithography and etching to form the lower electrode 11. Next, an insulating film was deposited on the silicon substrate and the lower electrode 11, and an opening of 1 square mm to which the lower electrode 11 is to be exposed was formed by lithography and etching. Subsequently, the silicon substrate was washed by means of a UV/ozone treatment, and then the silicon substrate was transferred to a vacuum deposition apparatus. While rotating a substrate holder in such a state that a deposition vessel was reduced to 1×10⁻⁵ Pa or less, the n-buffer layer 12, the photoelectric conversion layer 13, and the p-buffer layer 14 were sequentially deposited on the lower electrode 11. Specifically, a perylene-3,4,9,10-tetracarboxylic dianhydride (PTCDA) derivative represented by the following formula (1) was deposited at a substrate temperature of 40° C. and at a thickness of 10 nm. Subsequently, fullerene C₆₀ represented by the following formula (2), 5,5′-Di(9H-fluoren-2-yl)-2,2′-bithiophene (FTTF) represented by the following formula (3), and 2-((Z)-2-((E)-2-(1,1-dimethyl-5,6-dihydro-4H-pyrrolo[3,2,1-ij]quinoline-2(1H)-yliden) ethyliden)-3-oxo-2,3-dihydro-1H-inden-1-yliden)malononitrile, 2-[(Z)-2-[(E)-2-(5,6-dihydro-1,1-dimethyl-4H-pyrrolo[3,2,1-ij]quinoline-2(1H)-yliden)-ethyliden]-2,3-dihydro-3-oxo-1H-inden-1-yliden]propanedinitrile (HB194) represented by the formula (4) were deposited at a substrate temperature of 40° C. and at deposition rates of 0.5 Å/sec, 0.5 Å/sec, and 0.5 Å/sec, respectively, at a thickness of 400 nm to afford the photoelectric converting layer 13. Next, tris (4-carbazoyl-9-ylphenyl) amine (TCTA) represented by the following formula (5) was deposited at a substrate temperature of 0° C. and at a thickness of 10 nm to afford the p-buffer layer 14. Finally, a silicon substrate was transferred to a sputtering apparatus, and an ITO film having a thickness of 50 nm was deposited on the p-buffer layer 14 to afford the upper electrode 15. Thereafter, a silicon substrate was subjected to an annealing treatment in a nitrogen atmosphere at 150° C. for 210 minutes to afford an evaluation element. In a light resistance test, the evaluation element was irradiated with pseudo sunlight for a predetermined period of time in a test atmosphere at a room temperature.

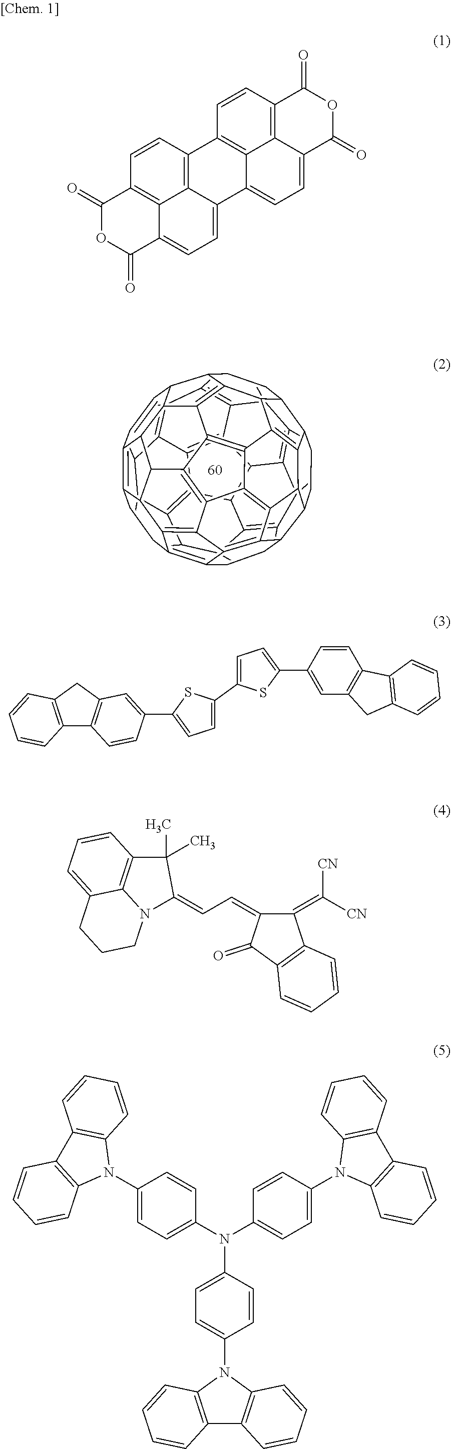

### Experimental Example 2

A method similar to that in Experimental Example 1 was used to prepare an evaluation element, except that the p-buffer layer 14 formed in Experimental Example 1 was formed using 3,3′-di(9H-carbazol-9-yl)-1,1′-biphenyl (m-CBP) represented by the following formula (6).

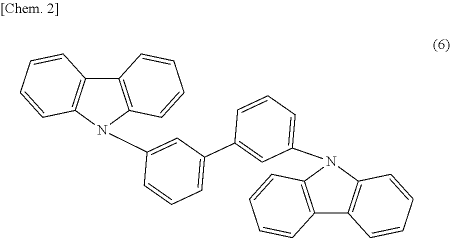 [SMILES: c1cc(-c2cccc(-n3c4ccccc4c4ccccc43)c2)cc(-n2c3ccccc3c3ccccc32)c1]

### Experimental Example 3

A method similar to that in Experimental Example 1 was used to prepare an evaluation element, except that the p-buffer layer 14 formed in Experimental Example 1 was formed using 1,3-bis(N-carbazolyl) benzene (mCP) represented by the following formula (7).

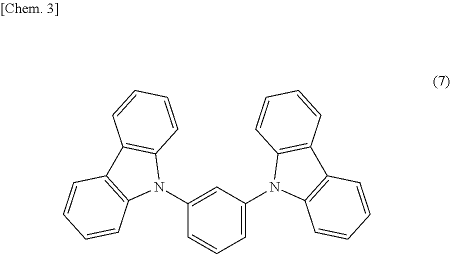 [SMILES: c1cc(-n2c3ccccc3c3ccccc32)cc(-n2c3ccccc3c3ccccc32)c1]

### Experimental Example 4

A method similar to that in Experimental Example 1 was used to prepare an evaluation element, except that 2-(3,6-bis (di-p-tolylamino)-9H-fluoren-9-ylidene) malononitrile (3,6-DTNFMN) represented by the following formula (8) was used instead of the HB194 represented by the formula (3) for the photoelectric conversion layer 13 formed in Experimental Example 1.

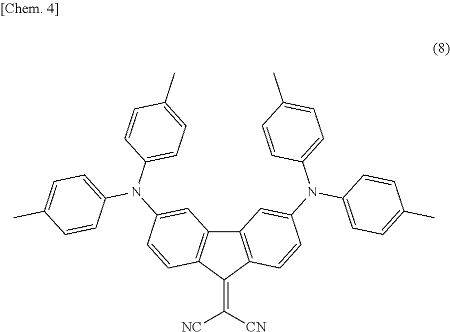

For Experimental Examples 1 to 4, the carrier mobility (u), the carrier lifetime (t), and the carrier range (L) of each of the n-buffer layer 12, the photoelectric conversion layer 13, and the p-buffer layer 14 were measured using the methods described above. Further, for Experimental Examples 1 to 4, the external quantum efficiency (EQE) and photoresponsivity were evaluated as element characteristics. The EQE and the photoresponsivity were evaluated using the following methods.

### (Evaluation of External Quantum Efficiency)

A wavelength of light to be irradiated to the evaluation element from a green LED light source via a band-pass filter was set to 560 nm, and an amount of the light was set to 1.62 μW/cm². A bias voltage to be applied between electrodes of the evaluation element was controlled using a semiconductor parameter analyzer, and a voltage applied to the lower electrode 11 with respect to the upper electrode 15 was swept to thereby obtain a current-voltage curve. A dark current value and a light current value in a reverse bias application state (a state where a voltage of +2.6V is applied) were acquired to subtract the dark current value from the light current value, and the number of incident photons were divided from the subtracted value to thereby calculate the external quantum efficiency (EQE).

As for the photoresponsivity, a speed was measured at which a light current value observed upon light irradiation falls after the light irradiation was stopped, using a semiconductor parameter analyzer. Specifically, the amount of light (LED light having a wavelength of 560 nm) to be irradiated from the light source to a photoelectric conversion element via the filter was set to 1.62 μW/cm², and the bias voltage to be applied between the electrodes was set to +2.6 V. After a steady current was observed in this state, the light irradiation was stopped, and the current was observed to be attenuated. Subsequently, an area surrounded by a current-time curve and a dark current was set to 100%, and time until this area corresponded to 3% was defined as an index of the photoresponsivity. All of these evaluations were made at a room temperature.

Tables 1 summarize materials used for the n-buffer layer 12, the photoelectric conversion layer 13 and the p-buffer layer 14 in Experimental Examples 1 to 4, carrier ranges of the n-buffer layer 12, the photoelectric conversion layer 13 and the p-buffer layer 14, and element characteristics of each of the evaluation elements. As for the carrier range, when the electric field intensity ranges from 10⁴ V/cm to 10⁶ V/cm, A denotes a case that satisfies the carrier mobility of 10⁻⁵ cm²/Vs to 10⁻² cm²/Vs, the carrier lifetime of 0.010 μs to 1.0 μs, and the carrier range of 10 nm or more, and B denotes a case that does not satisfy the carrier mobility of 10⁻⁵ cm²/Vs to 10⁻² cm²/Vs, the carrier lifetime of 0.010 μs to 1.0 μs, and the carrier range of 10 nm or more. The values of the EQE and the photoresponsivity are expressed as relative values in a case where the characteristic value of Experimental Example 1 is set to 1.0 (standard value).

TABLE 1

| | | | | | | | Element Characteristics | | | |
|---|---|---|---|---|---|---|---|---|---|---|
| | Material of | | | Carrier Range | | | | | | Degradation |
| | Photoelectric | Material of | Material of | Photoelectric | | | | Degradation | Photore- | Rate of |
| | Conversion | p-Buffer | n-Buffer | Conversion | p-Buffer | n-Buffer | | Rate of | sponsivity | Photore- |
| | Layer | Layer | Layer | Layer | Layer | Layer | EQE | EQE | (a.u.) | sponsivity |
| Experimental | Formula (2): | Formula (5) | Formula (1) | A | A | A | 1.0 | 1.0 | 1.0 | 1.0 |
| Example 1 | Formula (3): | | | | | | (Standard | (Standard | (Standard | (Standard |
| | Formula (4) | | | | | | Value) | Value) | Value) | Value) |
| Experimental | Formula (2): | Formula (6) | Formula (1) | A | A | A | 1.0 | 1.0 | 1.0 | 1.0 |
| Example 2 | Formula (3): | | | | | | | | | |
| | Formula (4) | | | | | | | | | |
| Experimental | Formula (2): | Formula (7) | Formula (1) | A | B | A | 0.85 | 0.88 | 1.8 | 2.7 |
| Example 3 | Formula (3): | | | | | | | | | |
| | Formula (4) | | | | | | | | | |
| Experimental | Formula (2): | Formula (5) | Formula (1) | B | A | A | 0.84 | 0.89 | 1.7 | 2.0 |
| Example 4 | Formula (3): | | | | | | | | | |
| | Formula (8) | | | | | | | | | |

In Experimental Examples 1 and 2 that satisfied, when the electric field intensity ranged from 10⁴ V/cm to 10⁶ V/cm, the carrier mobility of 10⁻⁵ cm²/Vs to 10⁻² cm²/Vs, the carrier lifetime of 0.010 μs to 1.0 μs, and the carrier range of 10 nm or more, the n-buffer layer 12, the photoelectric conversion layer 13, and the p-buffer layer 14 had favorable initial element characteristics. In addition, the photopolymerization of the electron-transporting material (fullerene C₆₀) was suppressed, thus allowing the variation in the element characteristics to be decreased before and after the light resistance. Meanwhile, in Experimental Examples 3 and 4 in which the photoelectric conversion layer 13 (Experimental Example 4) and the p-buffer layer 14 (Experimental Example 3) did not satisfy the above-mentioned range, the initial element characteristics was poor, and the variation in the element characteristics was increased before and after the light resistance.

Description has been given hereinabove of the present technology by referring to the embodiment, Modification Examples 1 to 5 and Examples as well as the application examples and the practical application examples; however, the content of the present disclosure is not limited to the foregoing embodiment and the like, and may be modified in a wide variety of ways. For example, the foregoing embodiment and the like exemplify electrons being read as signal charge from the side of the lower electrode 11, but this is not limitative; holes may be read as signal charge from the side of the lower electrode 11. In that case, the p-buffer layer 14 is provided between the lower electrode 11 and the photoelectric conversion layer 13, and the n-buffer layer 12 is provided between the upper electrode 15 and the photoelectric conversion layer 13.

In addition, in the foregoing embodiment, the imaging element 1A has a configuration in which the photoelectric conversion section 10 that uses an organic material and detects green light (G) and the photoelectric conversion region 32B and the photoelectric conversion region 32R that detect, respectively, blue light (B) and red light (R) are stacked. However, the content of the present disclosure is not limited to such a structure. That is, red light (R) or blue light (B) may be detected in the photoelectric conversion section using an organic material, or green light (G) may be detected in the photoelectric conversion region including an inorganic material.

Further, the numbers of the photoelectric conversion section using the organic material and the photoelectric conversion region including the inorganic material, and the ratio therebetween are not limitative. Furthermore, the configuration in which the photoelectric conversion section using the organic material and the photoelectric conversion region including the inorganic material are stacked in the vertical direction is not limitative; they may be arranged side by side along a substrate surface.

In addition, although the foregoing embodiment and the like exemplify the configuration of the back side illumination imaging element, the content of the present disclosure is also applicable to a front side illumination imaging element.

Further, the photoelectric conversion element 10, the imaging element 1A or the like, and the imaging device 100 of the present disclosure need not necessarily include all of the components described in the foregoing embodiment, and may include any other component, conversely. For example, the imaging device 100 may be provided with a shutter to control the incidence of light on the imaging element 1A, or may be provided with an optical cut filter depending on the objective of the imaging device 100. In addition, the arrangement of the pixels (Pr, Pg, and Pb) that detect red light (R), green light (G), and blue light (B) may be, in addition to the Bayer arrangement, an interline arrangement, a G stripe RB checkered arrangement, a G stripe RB complete checkered arrangement, a checkered complementary color arrangement, a stripe arrangement, a diagonal stripe arrangement, a primary-color color difference arrangement, a field color difference sequential arrangement, a frame color difference sequential arrangement, a MOS-type arrangement, an improved MOS-type arrangement, a frame interleave arrangement, or a field interleave arrangement.

Furthermore, although the foregoing embodiment and the like exemplify the use of the photoelectric conversion element 10 as an imaging element, the photoelectric conversion element 10 of the present disclosure may be applied to a solar cell. In the case of the application to the solar cell, the photoelectric conversion layer is preferably designed to broadly absorb a wavelength of 400 nm to 800 nm, for example.

It is to be noted that the effects described herein are merely exemplary and are not limitative, and may further include other effects.

It is to be noted that the present technology may also have the following configurations. According to the present technology of the following configurations, the organic layer having a carrier mobility of 10⁻⁵ cm²/Vs or more and 10⁻² cm²/Vs or less, a carrier lifetime of 0.010 μs or more and 1.0 μs or less, and a carrier range of 10 nm or more and 1 μm or less is provided between a first electrode and a second electrode disposed to be opposed to each other. This improves the initial element characteristics without using a quencher. It is therefore possible to improve light resistance.

(1)

A photoelectric conversion element including:
a first electrode;
a second electrode disposed to be opposed to the first electrode; and
an organic layer provided between the first electrode and the second electrode, the organic layer having a carrier mobility of 10⁻⁵ cm²/Vs or more and 10⁻² cm²/Vs or less, a carrier lifetime of 0.010 μs or more and 1.0 μs or less, and a carrier range of 10 nm or more and 1 μm or less.
   (2)

The photoelectric conversion element according to (1), in which an electric field intensity to be applied to the organic layer is 10⁴ V/cm or more and 10⁶ V/cm or less.

(3)

The photoelectric conversion element according to (1) or (2), in which the organic layer includes a p-buffer layer having hole transportability, a photoelectric conversion layer, and an n-buffer layer having electron transportability.

(4)

The photoelectric conversion element according to (3), in which the n-buffer layer, the photoelectric conversion layer, and the p-buffer layer are stacked in this order from a side of the first electrode or a side of the second electrode.

(5)

The photoelectric conversion element according to (3) or (4), in which
the carrier mobility and the carrier lifetime are hole mobility and a hole lifetime, respectively, in the p-buffer layer, and
the carrier mobility and the carrier lifetime are electron mobility and an electron lifetime, respectively, in the n-buffer layer.
   (6)

The photoelectric conversion element according to any one of (3) to (5), in which the photoelectric conversion layer includes a fullerene or a fullerene derivative.

(7)

The photoelectric conversion element according to any one of (3) to (6), in which the photoelectric conversion layer further includes a coloring material that absorbs light in a predetermined wavelength region while transmitting light in another wavelength region.

(8)

The photoelectric conversion element according to any one of (1) to (7), in which the first electrode includes a plurality of electrodes independent of each other.

(9)

The photoelectric conversion element according to (8), in which respective voltages are applied individually to the plurality of electrodes.

(10)

A photodetector including a plurality of pixels each including a photoelectric conversion element that includes one or a plurality of photoelectric conversion sections,
the photoelectric conversion section including
   a first electrode,
   a second electrode disposed to be opposed to the first electrode, and
   an organic layer provided between the first electrode and the second electrode, the organic layer having a carrier mobility of 10⁻⁵ cm²/Vs or more and 10⁻² cm²/Vs or less, a carrier lifetime of 0.010 μs or more and 1.0 μs or less, and a carrier range of 10 nm or more and 1 μm or less.
      (11)

The photodetector according to (10), in which the photoelectric conversion element further includes one or a plurality of photoelectric conversion regions that performs photoelectric conversion of a wavelength region different from the one or the plurality of photoelectric conversion sections.

(12)

The photodetector according to (11), in which
the one or the plurality of photoelectric conversion regions is formed to be embedded in a semiconductor substrate, and
the one or the plurality of photoelectric conversion sections is disposed on a side of a light incident surface of the semiconductor substrate.
   (13)

The photodetector according to (12), in which a multilayer wiring layer is formed on a surface of the semiconductor substrate on a side opposite to the light incident surface.

(14)

An electronic apparatus including a photodetector, the photodetector including a plurality of pixels each including a photoelectric conversion element that includes one or a plurality of photoelectric conversion sections,
the photoelectric conversion section including
   a first electrode,
   a second electrode disposed to be opposed to the first electrode, and
   an organic layer provided between the first electrode and the second electrode, the organic layer having a carrier mobility of 10⁻⁵ cm²/Vs or more and 10⁻² cm²/Vs or less, a carrier lifetime of 0.010 μs or more and 1.0 μs or less, and a carrier range of 10 nm or more and 1 μm or less.

The present application claims the benefit of Japanese Priority Patent Application JP2022-030442 filed with the Japan Patent Office on Feb. 28, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A photoelectric conversion element comprising:
a first electrode;
a second electrode disposed to be opposed to the first electrode; and
an organic layer provided between the first electrode and the second electrode, the organic layer having a carrier mobility of 10⁻⁵ cm²/Vs or more and 10⁻² cm²/Vs or less, a carrier lifetime of 0.010 μs or more and 1.0 μs or less, and a carrier range of 10 nm or more and 1 μm or less.

2. The photoelectric conversion element according to claim 1, wherein an electric field intensity to be applied to the organic layer is 10⁴ V/cm or more and 10⁶ V/cm or less.

3. The photoelectric conversion element according to claim 1, wherein the organic layer includes a p-buffer layer having hole transportability, a photoelectric conversion layer, and an n-buffer layer having electron transportability.

4. The photoelectric conversion element according to claim 3, wherein the n-buffer layer, the photoelectric conversion layer, and the p-buffer layer are stacked in this order from a side of the first electrode or a side of the second electrode.

5. The photoelectric conversion element according to claim 3, wherein
the carrier mobility and the carrier lifetime are hole mobility and a hole lifetime, respectively, in the p-buffer layer, and
the carrier mobility and the carrier lifetime are electron mobility and an electron lifetime, respectively, in the n-buffer layer.

6. The photoelectric conversion element according to claim 3, wherein the photoelectric conversion layer includes a fullerene or a fullerene derivative.

7. The photoelectric conversion element according to claim 3, wherein the photoelectric conversion layer further includes a coloring material that absorbs light in a predetermined wavelength region while transmitting light in another wavelength region.

8. The photoelectric conversion element according to claim 1, wherein the first electrode includes a plurality of electrodes independent of each other.

9. The photoelectric conversion element according to claim 8, wherein respective voltages are applied individually to the plurality of electrodes.

10. A photodetector comprising a plurality of pixels each including a photoelectric conversion element that includes one or a plurality of photoelectric conversion sections,
the photoelectric conversion section including
a first electrode,
a second electrode disposed to be opposed to the first electrode, and
an organic layer provided between the first electrode and the second electrode, the organic layer having a carrier mobility of 10⁻⁵ cm²/Vs or more and 10⁻² cm²/Vs or less, a carrier lifetime of 0.010 μs or more and 1.0 μs or less, and a carrier range of 10 nm or more and 1 μm or less.

11. The photodetector according to claim 10, wherein the photoelectric conversion element further includes one or a plurality of photoelectric conversion regions that performs photoelectric conversion of a wavelength region different from the one or the plurality of photoelectric conversion sections.

12. The photodetector according to claim 11, wherein
the one or the plurality of photoelectric conversion regions is formed to be embedded in a semiconductor substrate, and
the one or the plurality of photoelectric conversion sections is disposed on a side of a light incident surface of the semiconductor substrate.

13. The photodetector according to claim 12, wherein a multilayer wiring layer is formed on a surface of the semiconductor substrate on a side opposite to the light incident surface.

14. An electronic apparatus comprising a photodetector, the photodetector including a plurality of pixels each including a photoelectric conversion element that includes one or a plurality of photoelectric conversion sections,
the photoelectric conversion section including
a first electrode,
a second electrode disposed to be opposed to the first electrode, and
an organic layer provided between the first electrode and the second electrode, the organic layer having a carrier mobility of 10⁻⁵ cm²/Vs or more and 10⁻² cm²/Vs or less, a carrier lifetime of 0.010 μs or more and 1.0 μs or less, and a carrier range of 10 nm or more and 1 μm or less.
